(19) United States
(12) Patent Application Publication
(10) Pub. No.: US 2026/0235970 A1
(43) Pub. Date: Aug. 13, 2026

(54) SUBSTRATE PROCESSING APPARATUS AND SUBSTRATE PROCESSING METHOD

(71) Applicant: Tokyo Electron Limited, Tokyo (JP)

(72) Inventors: Yoji SAKATA, Kumamoto (JP); Ryohei FUJISE, Kumamoto (JP); Shinsuke TAKAKI, Kumamoto (JP); Yu YOSHIMOTO, Kumamoto (JP); Seiji NAGAHARA, Tokyo (JP); Tomoya ONITSUKA, Kumamoto (JP)

(73) Assignee: Tokyo Electron Limited, Tokyo (JP)

(21) Appl. No.: 19/156,401

(22) PCT Filed: Feb. 6, 2024
(86) PCT No.: PCT/JP2024/003965

§ 371 Date: Aug. 14, 2025

(30) Foreign Application Priority Data
Feb. 15, 2023 (JP) 2023-021401
Nov. 22, 2023 (JP) 2023-198388

(51) Int. Cl. G03F 7/00

(52) U.S. Cl. CPC G03F 7/70991; G03F 7/7075; G03F 7/70875; G03F 7/70925

(57) ABSTRACT

A wafer processing system is a substrate processing apparatus that executes a process related to EUV patterning comprising, and the system includes first processing devices each of which executes a process on the wafer W to which CAR is applied, and second processing devices each of which executes a process on the wafer W to which MOR is applied. Processing spaces of the first processing devices and processing spaces of the second processing devices are sectioned from each other. The plurality of second processing devices executes processes corresponding to the respective first processing devices.

### FIELD

Exemplary embodiment disclosed herein relates to a substrate processing apparatus and a substrate processing method.

### BACKGROUND

Patent Literature 1 discloses a substrate processing apparatus that is configured to apply, in photolithography, resist to a wafer so as to form thereon a resist film, to supply liquid developer thereto so as to develop an exposed resist film, and the like.

### CITATION LIST

### Patent Literature

Japanese Patent Application Laid-open No. 2010-219434

### SUMMARY

### Technical Problem

The present disclosure provides a technology capable of efficiently executing Extra Ultra Violet (EUV) patterning.

### Solution to Problem

A substrate processing apparatus according to one aspect of an embodiment includes: a plurality of first processing devices each of which executes a process for applying a chemically amplified resist to a substrate; and a plurality of second processing devices each of which executes a process for applying a metal containing resist to a substrate. Processing spaces of the first processing devices and processing spaces of the second processing devices are sectioned from each other, and the plurality of second processing devices executes processes corresponding to the respective first processing devices.

### Advantageous Effects of Invention

According to the present disclosure, it is possible to efficiently perform EUV patterning.

### BRIEF DESCRIPTION OF DRAWINGS

FIG. 1 is a plan view schematically illustrating the outline of a configuration of a wafer processing system.

FIG. 2 is a front view schematically illustrating the outline of the wafer processing system.

FIG. 3 is a diagram illustrating a modification of an interface station.

FIG. 4 is a diagram illustrating movement of a wafer transfer device illustrated in FIG. 3.

FIG. 5 is a diagram illustrating a first block.

FIG. 6 (a) is a front view schematically illustrating one example of a layout of a transfer device in a fifth block; and FIG. 6 (b) is a front view schematically illustrating another example of a layout of the transfer device in the fifth block.

FIG. 7 is a perspective view schematically illustrating a nitrogen atmosphere placement part of a slot structure that is arranged in the transfer device of the fifth block.

FIG. 8 is a plan view schematically illustrating the nitrogen atmosphere placement part of the slot structure.

FIG. 9 is a diagram illustrating a side flow in the nitrogen atmosphere placement part of the slot structure.

FIG. 10 is a side view schematically illustrating a nitrogen atmosphere placement part of a slot structure according to a modification.

FIG. 11 (a) is a perspective view illustrating a shutter state under a “OPEN-A” mode, FIG. 11 (b) is a front view illustrating a shutter state under the “OPEN-A” mode, and FIG. 11 (c) is a table indicating UP or DOWN Of cylinders under the “OPEN-A” mode; and FIG. 11 (d) is a perspective view illustrating a shutter state under a “OPEN-B” mode, FIG. 11 (e) is a front view illustrating a shutter state under the “OPEN-B” mode, and FIG. 11 (f) is a table indicating UP or DOWN of the cylinders under the “OPEN-B” mode. FIG. 11 (g) is a perspective view a shutter state under a “FULL-CLOSE” mode, FIG. 11 (h) is a front view illustrating a shutter state under the “FULL-CLOSE” mode, and FIG. 11 (i) is a table indicating UP or DOWN of the cylinders under the “FULL-CLOSE” mode.

FIG. 12 (a) is a side view schematically illustrating a shutter state under the “OPEN-A” mode, and FIG. 12 (b) is a side view schematically illustrating a shutter state under the “OPEN-B” mode. FIG. 12 (c) is a side view schematically illustrating a shutter state under the “FULL-CLOSE” mode.

FIG. 13 (a) is a plan view schematically illustrating one example of a layout of a heat processing unit and the like in a second block, and FIG. 13 (b) is a plan view schematically illustrating another example of a layout of the heat processing unit and the like in the second block.

FIG. 14 is a cross-sectional view schematically illustrating the nitrogen atmosphere placement part having a chamber structure, which is arranged on a cooling plate connected with a heat plate.

FIG. 15 (a) is a cross-sectional view schematically illustrating one example of the nitrogen atmosphere adjustment unit having a chamber structure that is arranged on an independently-provided cooling plate, and FIG. 15 (b) is a cross-sectional view schematically illustrating another example of the nitrogen atmosphere adjustment unit having the chamber structure that is arranged on an independently-provided cooling plate.

FIG. 16 is a cross-sectional view schematically illustrating the outline of a cleaning module that is provided instead of an MOR dedicated developing module.

FIG. 17 is a cross-sectional view schematically illustrating a cleaning module that is provided in the MOR dedicated applying module.

### DESCRIPTION OF EMBODIMENTS

Hereinafter, a wafer processing system as a substrate processing apparatus according to the present embodiment will be described in detail with reference to the accompanying drawings. Note that the same reference symbol is provided to elements including substantially the same functional configuration so as to omit duplicated explanation.

### Wafer Processing System

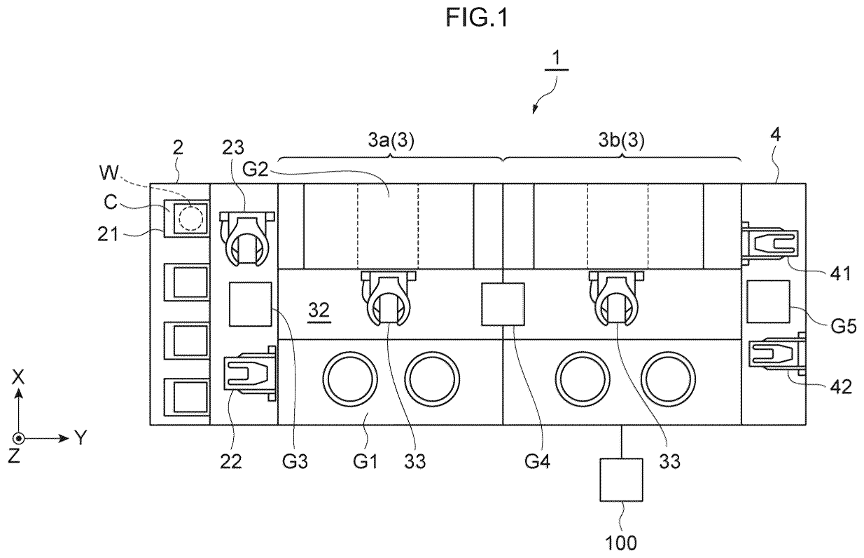

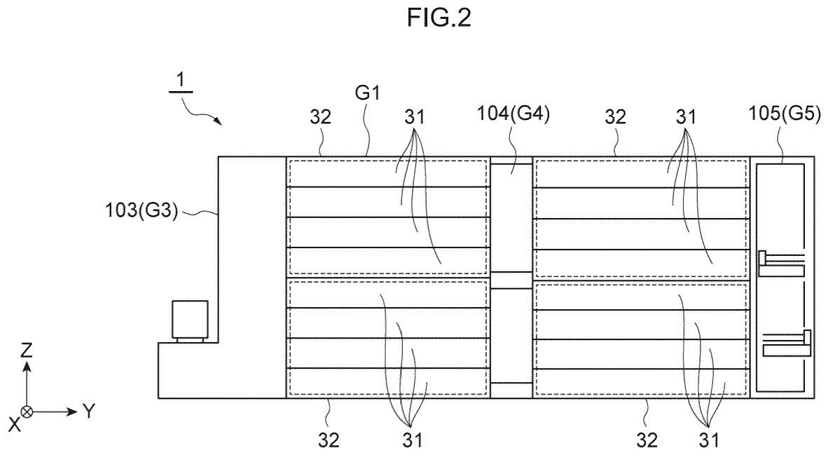

A configuration of a wafer processing system according to the present embodiment will be explained. FIGS. 1 and 2 are a plan view and a front view, each of which illustrates the outline of a configuration of a wafer processing system 1. In the present embodiment, a case of a photolithography processing system will be explained as one example, in which the wafer processing system 1 executes a forming process and a developing process of a resist film on a wafer W. The wafer processing system 1 is a substrate processing apparatus that is configured to execute processing related to Extra Ultra Violet (EUV) patterning.

As illustrated in FIG. 1, the wafer processing system 1 includes a cassette station 2 into/from which a cassette C housing therein the plurality of wafers W is carried, and a processing station 3 including various processing devices configured to execute predetermined processes on the wafer W. The wafer processing system 1 has a configuration in which the cassette station 2, the processing station 3, and an interface station 4 are integrally connected to each other. The interface station 4 transfers the wafer W to and from an exposure device (not illustrated) that is adjacent to an opposite side of the processing station 3. Note that as illustrated in FIG. 1, the processing station 3 is divided into a first region 3a close to the cassette station 2 and a second region 3b close to the interface station 4 in a left-and-right direction that intersects with the vertical direction. In other words, in the processing station 3, two parts of a part corresponding to the first region 3a and a part corresponding to the second region 3b are arranged. Note that the division number of the processing station 3 (in other words, the number of parts obtained by division) is not limited to two, may be three or more, or may be one.

In the cassette station 2, a plurality of cassette placing pedestals 21 and wafer transfer devices 22 and 23 are provided. In the cassette station 2, the wafer transfer device 22 or the wafer transfer device 23 transfers the wafer W between the processing station 3 and the cassette C placed in the cassette placing pedestal 21. Thus, each of the wafer transfer devices 22 and 23 may include a drive mechanism for any of directions of an X direction, a Y direction, a vertical direction, and a direction around a vertical axis (namely, O direction) as needed, or may include a drive mechanism for all directions. At least one of the wafer transfer devices 22 and 23 is capable of carrying the wafer W to and from the cassette C, and further is capable of executing a transfer operation of the wafer W with respect to the processing station 3. The transfer operation of the wafer W with respect to the processing station 3 is to carry a wafer to and from a third block G3 including a transfer device that can be accessed by a wafer transfer device 33 to be mentioned later in the processing station 3, for example. The transfer device in the third block G3 may be a tower-shaped transfer device 103 (see FIG. 2) in which a plurality of housing spaces is formed in a vertically multistage manner, for example.

Note that an inspection device (not illustrated) configured to execute inspection on the wafer W may be arranged in position that can be accessed by at least one of the wafer transfer devices 22 and 23.

In the processing station 3, a plurality of blocks, for example, a first block G1, a second block G2, and a fourth block G4 are provided. For example, the first block G1 is arranged on a front side (see negative-X direction side of FIG. 1) of the processing station 3, and the second block G2 is arranged on a back side (see positive-X direction of FIG. 1) of the processing station 3. As illustrated in FIG. 2, a plurality of layers 31 is vertically laminated in the first block G1. Similarly, also in the second block G2, the plurality of layers 31 is vertically laminated. The fourth block G4 is arranged in a region in the Y direction between the first region 3a and the second region 3b of the processing station 3 and in the X direction between the first block Gl and the second block G2. The fourth block G4 may include a transfer device. The transfer device in the fourth block G4 may be a tower-shaped transfer device 104 (namely, second tower) in which a plurality of housing spaces is formed in a vertically multistage manner, each of which accommodates therein the wafer W, for example. Note that the above-mentioned third block G3 may be arranged in the processing station 3.

In the first block G1, a plurality of liquid processing devices is arranged, such as a not-illustrated patterning dedicated film forming device and a not-illustrated exposure processing device. As the patterning dedicated film forming device, for example, a reflection preventing film forming device may be employed in addition to a resist film forming device.

In the first block G1, for example, a plurality of processing devices is arranged side-by-side along a horizontal direction. Note that the number, arrangement, and types of the processing devices may be arbitrarily decided.

In the patterning dedicated film forming device and the exposure processing device, for example, predetermined processing liquid or predetermined gas is supplied onto the wafer W. As described above, in the patterning dedicated film forming device, a resist film to be used as a mask in forming a pattern of a film on a lower layer side, a reflection preventing film for efficiently executing a light irradiating process such as an exposing process, and the like are formed. On the other hand, in the exposure processing device, a part of the exposed resist film is removed so as to form an uneven shape as the above-mentioned mask.

For example, in the second block G2, heat processing units (not illustrated) for executing thermal treatments such as heating and/or cooling of the wafer W are aligned in the vertical direction and the horizontal direction. In the second block G2, although illustration thereof is omitted, hydrophobization processing devices each of which is configured to execute a hydrophobization process for improving fixability between liquid resist and the wafer W, and periphery exposure devices each of which is configured to expose a peripheral portion of the wafer W are aligned in the vertical direction (see Z direction illustrated in FIG. 2) and the horizontal direction. The numbers and arrangement of the heat processing units, the hydrophobization processing devices, and the periphery exposure devices may be arbitrarily selected.

As illustrated in FIG. 1, in a plan view, a wafer transferring region 32 is formed in a region between the first block G1 and the second block G2. The wafer transfer devices 33 are arranged in the wafer transferring region 32, for example.

The wafer transfer device 33 includes a transfer arm that is capable of moving in the Y direction, a forward and backward direction, a e direction, and a vertical direction, for example. The wafer transfer device 33 is capable of moving in the wafer transferring region 32 so as to transfer the wafer W into a predetermined device in the first block G1, the second block G2, the third block G3, and the fourth block G4 in the surroundings. As illustrated in FIG. 1, in a case where the first region 3a and the second region 3b are arranged in the processing station 3, the wafer transfer device 33 arranged in the first region 3a is capable of transferring the wafer W into the first block G1, the second block G2, and the third block G3. The wafer transfer device 33 arranged in the second region 3b is capable of transferring the wafer W to the first block G1, the second block G2, and a fifth block G5 to be mentioned later. The wafer transfer device 33 arranged in the second region 3b is capable of transferring the wafer W to a predetermined device arranged in the fifth blocl G5.

The plurality of wafer transfer devices 33 may be arranged in the vertical direction. One of the plurality of wafer transfer devices 33 is capable of transferring the wafer W into predetermined devices located at heights of the plurality of layers 31 on an upper side among the plurality of layers 31 (see FIG. 2) that is laminated in the vertical direction. The other wafer transfer device 33 is capable of transferring the wafer W to predetermined devices located at heights of the plurality of layers 31 on a lower side than the above-mentioned upper layers 31. The plurality of wafer transferring regions 32 (see FIG. 2) is arranged so as to realize the above-mentioned transfer of the wafer W. Note that the wafer transfer devices 33 may be arranged in the respective layers 31, for example, and the number of the wafer transfer devices 33 and/or the number of the layers 31 corresponding to the single wafer transfer device 33 may be arbitrarily selected.

A shuttle transfer device (not illustrated) may be arranged in the wafer transferring region 32, the first block G1, or the second block G2. The shuttle transfer device linearly transfers the wafer W between a space adjacent to one side of the processing station 3 and another space adjacent to an opposite side of the one side.

The interface station 4 is connected with the first block G1 and the second block G2 constituting a processing block, and further carries the wafer W into and form the exposure device. The fifth block G5 and wafer transfer devices 41 and 42 are arranged in the interface station 4. The interface station 4 causes the wafer transfer device 41 or the wafer transfer device 42 to transfer the wafer W between the exposure device and the fifth block G5 into/form which the wafer W is carried by the wafer transfer device 33. Thus, each of the wafer transfer devices 41 and 42 is provided with a drive mechanism as needed, which moves in a direction such as the X direction, the Y direction, the vertical direction, and a direction around a vertical axis (namely, θ direction); or may include a drive mechanism that moves in all of the directions. At least one of the wafer transfer devices 41 and 42 is capable of supporting the wafer W so as to transfer the wafer W between the exposure device and a transfer device in the fifth block G5. Herein, the transfer device in the fifth block G5 may be a tower-shaped transfer device 105 (namely, tower) (see FIG. 2) in which a plurality of housing spaces is formed in a vertically multistage manner, for example.

In the interface station 4, a cleaning device configured to clean a surface of the wafer W and/or the above-mentioned periphery exposure device may be arranged in a position to be accessed by at least one of the wafer transfer devices 41 and 42.

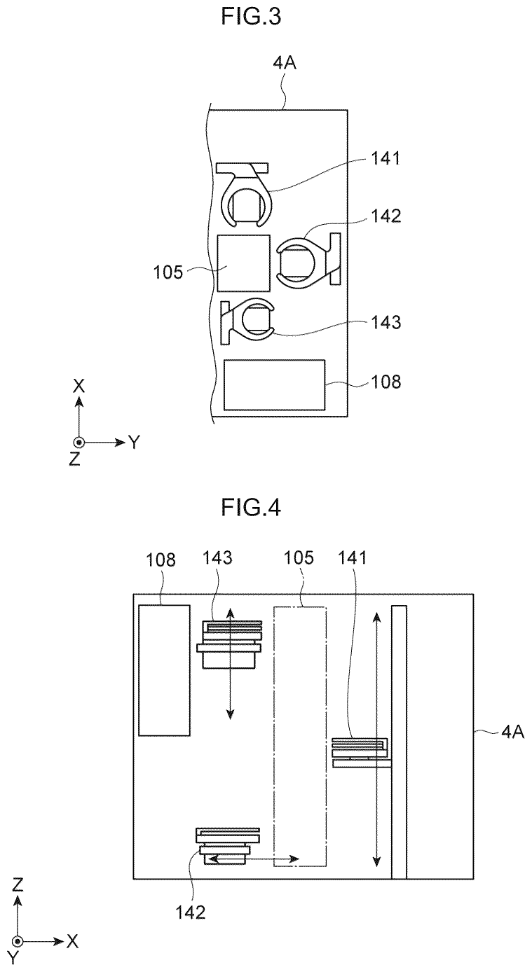

Note that a configuration of the interface station 4 is not limited to the configuration illustrated in FIG. 1, and may be that of an interface station 4A illustrated in FIG. 3 and FIG. 4, for example. The interface station 4A illustrated in FIG. 3 and FIG. 4 is provided with a placing part 108 on which the exposing-processed wafer W is placed, in addition to the transfer device 105. The placing part 108 is arranged in an end on a front side (see positive-X direction side illustrated in FIG. 3) of the interface station 4A. The placing part 108 may have a configuration that is the same or similar to that of a nitrogen atmosphere placement part 51 (see FIG. 3 (a)) to be mentioned later, or may have a configuration that is the same or similar to that of an air atmosphere placement part 55 (see FIG. 3 (a)) to be mentioned later. For example, the placing part 108 may be a nitrogen atmosphere placement part (to be mentioned later) on which the wafer W is placed, on which an exposing-processed MOR film is formed.

As illustrated in FIG. 3 and FIG. 4, the interface station 4A is provided with three wafer transfer devices 141, 142, and 143. The wafer transfer device 141 is arranged on a back side (see positive-X direction side illustrated in FIG. 3) of the interface station 4A so as to operate in a vertical direction. The wafer transfer device 142 is arranged on a side of the exposure device (see positive-Y direction side illustrated in FIG. 3) of the interface station 4A so as to operate in the X direction. The wafer transfer device 143 is arranged on a front side (see positive-X direction side illustrated in FIG. 3) of the interface station 4A, specifically, between the transfer device 105 and the placing part 108 with respect to the X direction, so as to operate in a vertical direction. Note that each of the wafer transfer devices 141, 142, and 143 may be capable of executing a rotational operation around a vertical direction and/or an operation in a reseating direction, in addition to directions indicated by arrows illustrated in FIG. 4.

An airflow generating unit may be arranged in the wafer processing system 1, which generates airflow. For example, the airflow generating unit is arranged in a ceiling portion of a target space, and further supplies thereto adjusted gas so as to generate airflow (namely, downflow) in a downward direction.

The above-mentioned wafer processing system 1 is provided with a control device 100. For example, the control device 100 is a computer so as to include a program storage (not illustrated). The program storage stores therein programs for controlling processes to be executed on the wafer W in the wafer processing system 1. The program storage also stores therein programs for controlling operations of drive systems of the above-mentioned various processing devices, transfer devices, and the like so as to realize wafer processing in the wafer processing system 1. Note that the above-mentioned programs may be recorded in a computer-readable storage medium H, and further may be installed into the control device 100 from the storage medium H.

### Operations of Wafer Processing System

The wafer processing system 1 is configured as described above. Next, one example of wafer processing will be explained, which is executed by using the wafer processing system 1 configured as described above.

The cassette C housing therein the plurality of wafers W is first carried in the cassette station 2 of the wafer processing system 1, and is placed on the cassette placing pedestal 21. Next, the wafer transfer device 22 or the wafer transfer device 23 takes out the wafers W in the cassette C one-by-one, and further transfers the wafers W to the transfer device 103 of the third block G3.

The wafer W transferred to the transfer device 103 of the third block G3 is supported by the wafer transfer device 33 to be transferred to a hydrophobization processing device arranged in the second block G2, and a hydrophobization process is executed thereon. Next, the wafer W is transferred to a resist film forming device by the wafer transfer device 33 so as to form a resist film on the wafer W. Next, the wafer W is transferred to a heat processing unit and a pre-bake process is executed thereon, and then is transferred to the transfer device 105 of the fifth block G5. Note that in a case where there presents the plurality of processing stations 3 as illustrated in FIGS. 1 and 2, the wafer W is once placed on the transfer device 104 of the fourth block G4 and then is transferred to the transfer device 105 of the fifth block G5 to be exchanged between the plurality of wafer transfer devices 33. The wafer W may be transferred to a periphery exposure device as needed by the wafer transfer device 33, and an exposing process may be executed on a periphery portion of the wafer W.

The wafer W having transferred to the transfer device 105 of the fifth block G5 is transferred to an exposure device by the wafer transfer devices 41 and 42, and further an exposing process is executed thereon with a predetermined pattern. Note that the wafer W may be cleaned by a cleaning device before the exposing process.

The exposing-processed wafer W is transferred to the transfer device 105 of the fifth block G5 by the wafer transfer devices 41 and 42. Next, the wafer W is transferred to a heat processing unit by the wafer transfer device 33, and further a post exposure bake process is executed thereon.

The post-exposure-bake-processed wafer W is transferred to an exposure processing device by the wafer transfer device 33 to be developed. After completion of the development, the wafer W is transferred to a heat processing unit by the wafer transfer device 33, and further a post bake process is executed thereon.

Next, the wafer W is transferred to the transfer device 103 of the third block G3 by the wafer transfer device 33, and further is transferred to the cassette C of the predetermined cassette placing pedestal 21 by the wafer transfer device 22 or the wafer transfer device 23 of the cassette station 2. As described above, a series of photolithography processes end.

### Configuration for Handling Photoresists Having Plurality of Types

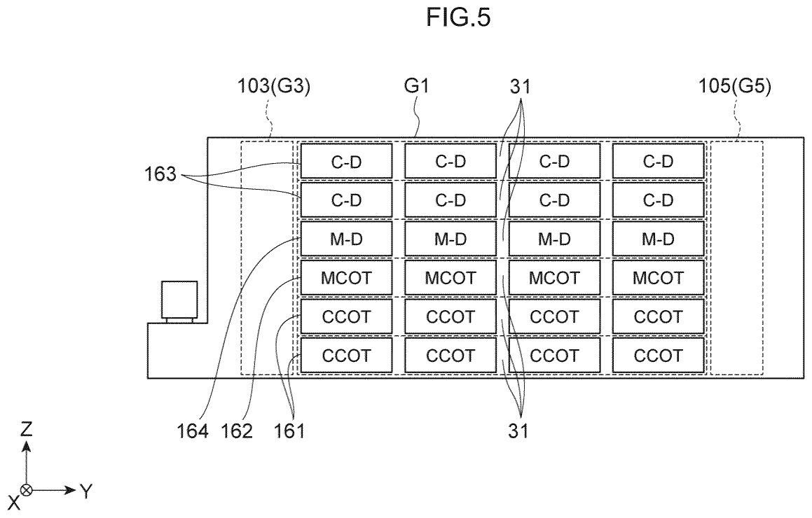

Next, with reference to FIG. 5 to FIG. 15, configurations for handling resists having a plurality of types will be explained. In the present embodiment, Metal Oxide Resist (MOR) that is a metal containing resist is used as resist for forming a pattern on the wafer W. In the present embodiment, as resist for forming a pattern on the wafer W, Chemical Amplification Resist (CAR) that is a chemically amplified resist is used. MOR is resist for changing difference in solubility between an exposed part and an unexposed part by using reaction of metal oxide, so as to form a pattern. An MOR film formed on a substrate includes a metal compound having a ligand. For one example, in a process for negative development, a part of ligands in a metal compound separates in an exposed part of an MOR film, and then the separated metals go into a connected state by a condensation reaction to be insoluble in negative liquid developer. MOR has a high resolution, and thus is employed in EUV lithography, for one example.

CAR is resist for amplifying reaction by reaction of a reaction catalyst generated in exposure so as to change solubility thereof in liquid developer.

The above-mentioned reactions starting from the separation of a part of ligands in an MOR film to the condensation reaction may be referred to as a series of reactions of the MOR film. In an MOR film formed on the wafer W, a water amount such as the humidity and the like, and concentrations of various gases in atmosphere of a space housing therein the wafer W affect proceeding of the above-mentioned series of reactions of the MOR film. Herein, in a case where the MOR film formed wafer W (namely, wafer W before and after exposure process) waits in normal atmospheric environment (namely, air), Critical Dimension (CD) fluctuates depending on a waiting time interval thereof and the like, and thus there presents possibility that a preferable pattern of the wafer W is not obtained. Thus, the wafer processing system 1 according to the present embodiment is configured to set a nitrogen concentration in atmosphere to be higher than that of air as a configuration for reducing fluctuation in CD (details thereof will be mentioned later). On the other hand, it is preferable that the CAR film formed wafer W (namely, wafer W before and after exposure process) wait in atmospheric environment. As described above, preferable environment for waiting is different between the MOR film formed wafer W and the CAR film formed wafer W. The wafer processing system 1 according to the present embodiment is provided with both of a configuration for processing the MOR film formed wafer W and a configuration for processing the CAR film formed wafer W in a sectioned manner so as to appropriately execute processes respectively corresponding MOR and CAR.

A first configuration example for handling resists having a plurality of types will be explained with reference to FIG. 5. FIG. 5 is a diagram illustrating the first block G1. In FIG. 5, illustration of the fourth block G4 is omitted. As illustrated in FIG. 5, in the first block Gl (namely, processing block) in which the plurality of layers 31 is vertically laminated, CAR dedicated applying devices 161 (indicated as “CCOT” in FIG. 5) are arranged, each of which forms a CAR film. MOR dedicated applying devices 162 (indicated as “MCOT” in FIG. 5), each of which forms an MOR film, and CAR dedicated developing devices 163 (indicated as “C-D” in FIG. 5), each of which executes a developing process after formation of a CAR film are also arranged therein. MOR dedicated developing devices 164 (indicated as “M-D” in FIG. 5), each of which executes a developing process after formation of an MOR film are also arranged therein. In the example illustrated in FIG. 5, the CAR dedicated applying devices 161 are arranged in the lowest layer 31 and the second lowest layer 31. The MOR dedicated applying devices 162 are arranged in the layer 31 on the second lowest layer 31. The MOR dedicated developing devices 164 are arranged in the layer 31 on the layer 31 of “MCOT”, and the CAR dedicated developing devices 163 are arranged in the uppermost layer 31 and the layers 31 just under the uppermost layer 31. Each of the layers 31 is provided with a plurality of corresponding devices (for example, four devices).

Each of the above-mentioned CAR dedicated applying device 161 and the above-mentioned CAR dedicated developing device 163 is a device constituting a first processing device that executes a process for applying CAR to the wafer W. Each of the above-mentioned MOR dedicated applying device 162 and the above-mentioned MOR dedicated developing device 164 is a device constituting a second processing device that executes a process for applying MOR to the wafer W. As described above, the CAR dedicated applying device 161, the MOR dedicated applying device 162, the CAR dedicated developing device 163, and the MOR dedicated developing device 164 are arranged in the respective layers 31 in the first block Gl so that processing spaces are sectioned from each other. The MOR dedicated applying device 162 executes a process (namely, resist film formation) corresponding to a process executed by the CAR dedicated applying device 161. The MOR dedicated developing device 164 executes a process (namely, development) corresponding to a process executed by the CAR dedicated developing device 163.

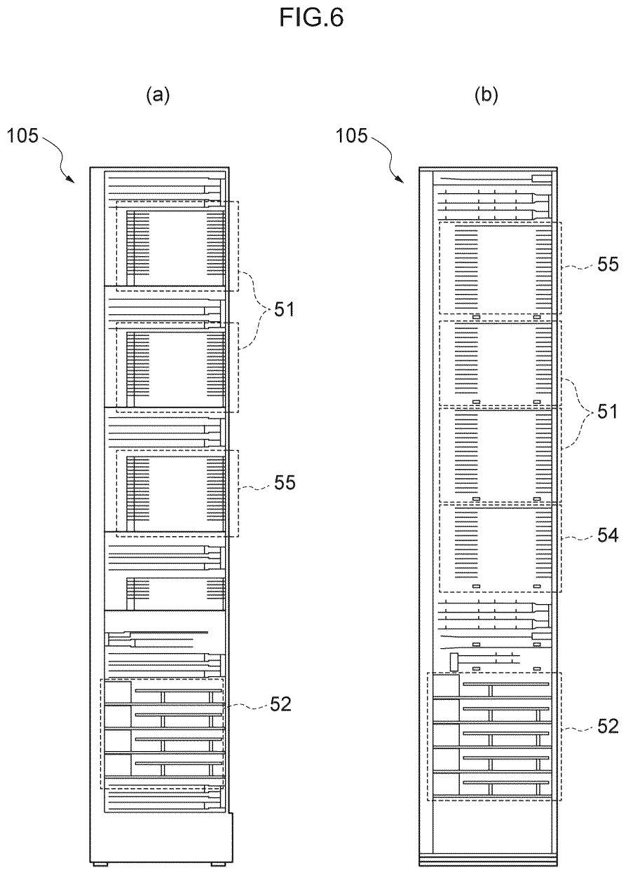

A second configuration example for handling resists having a plurality of types will be explained with reference to FIG. 6 to FIG. 12. FIG. 6 (a) is a front view schematically illustrating one example of a layout of the transfer device 105 of the fifth block G5.

The transfer device 105 (namely, first tower) is arranged in the fifth block G5 in which the wafer W is transferred to and from an exposure device (see FIG. 2), and as illustrated in FIG. 6 (a), is a tower-shaped device in which a plurality of housing spaces, each of which accommodates therein the wafer W, is formed in a vertically multistage manner.

The transfer device 105 includes, as a plurality of housing spaces, the nitrogen atmosphere placement parts 51 and 51 (namely, first nitrogen atmosphere placement parts), a pre-exposure cooling unit 52, and the air atmosphere placement part 55 (namely, first air atmosphere placement part), for example. In the example illustrated in FIG. 6 (a), in the transfer device 105, the nitrogen atmosphere placement parts 51 and 51 are respectively arranged in an uppermost stage and a stage just under the uppermost stage. In the transfer device 105, the pre-exposure cooling unit 52 is arranged in a lowermost stage, and the air atmosphere placement part 55 is arranged between the nitrogen atmosphere placement part 51 and the pre-exposure cooling unit 52.

As described above, the nitrogen atmosphere placement parts 51 are respectively arranged in two housing spaces in the transfer device 105. The nitrogen atmosphere placement part 51 has a configuration for supplying nitrogen in a state where the wafer W is placed such that the wafer W is placed in environment whose nitrogen concentration in atmosphere is set to be higher than that of air. It is sufficient that the nitrogen atmosphere placement part 51 is arranged in any of the housing spaces of the transfer device 105. The nitrogen atmosphere placement part 51 has a configuration on which the wafer w after formation of an MOR film and further before an exposure process is placed. Specifically, for example, the wafer W, which is an MOR film formed one and then is transferred to a heat processing unit to be pre-bake processed and that is before an exposure process, is placed on the nitrogen atmosphere placement part 51. As described above, the nitrogen atmosphere placement part 51 constitutes a second processing device for processing the MOR film formed wafer W. The nitrogen atmosphere placement part 51 is configured such that the plurality of wafers W can be placed thereon.

The air atmosphere placement part 55 has a configuration on which the wafer W after formation of an MOR film and before an exposure process is placed, and the wafer W is placed in atmospheric environment. The air atmosphere placement part 55 has a configuration on which the wafer W is placed where a resist film other than MOR is formed on the wafer W and it is preferable that the wafer W waits in atmospheric environment, for example. Specifically, the air atmosphere placement part 55 has a configuration on which the CAR film formed wafer W is placed. As described above, the air atmosphere placement part 55 constitutes a first processing device that processes the CAR film formed wafer W. The air atmosphere placement part 55 is arranged in one of housing spaces in the transfer device 105, in which the nitrogen atmosphere placement part 51 is not arranged. The air atmosphere placement part 55 is in common with the nitrogen atmosphere placement part 51 in that the wafer W before an exposure process is placed thereon; however, is different from the nitrogen atmosphere placement part 51 in that the wafer W is placed in atmospheric environment. The air atmosphere placement part 55 is configured such that the plurality of wafers W can be placed thereon. The air atmosphere placement part 55 has a configuration that is generally in common with that of the nitrogen atmosphere placement part 51 to be mentioned later, except that the air atmosphere placement part 55 does not include a configuration related to supply of nitrogen.

The pre-exposure cooling unit 52 has a configuration including a cooling plate that cools, before an exposure process, the wafer W where an MOR film is formed thereon and then is transferred to a heat processing unit to be pre-bake processed. The pre-exposure cooling unit 52 is configured to cool the plurality of wafers W.

A layout of the transfer device 105 is not limited to the mode illustrated in FIG. 6 (a). A layout of the transfer device 105 may have a mode illustrated in FIG. 6 (b), for example. FIG. 6 (b) is a front view schematically illustrating another example of a layout of the transfer device 105 of the fifth block G5.

In the example illustrated in FIG. 6 (b), in the transfer device 105, the air atmosphere placement part 55 is arranged in an uppermost stage, the nitrogen atmosphere placement parts 51 and 51 are arranged in two stages under the uppermost stage, and the pre-exposure cooling unit 52 is arranged in a lowermost stage. A nitrogen atmosphere placement part 54 is arranged between the nitrogen atmosphere placement part 51 and the pre-exposure cooling unit 52, on which the exposing processed MOR film formed wafer W is placed. As described above, in the example illustrated in FIG. 6 (b), the nitrogen atmosphere placement part 54 is arranged in the transfer device 105, on which the exposing processed MOR film formed wafer W is placed. The nitrogen atmosphere placement part 54 may have a configuration that is the same or similar to a configuration of the above-mentioned nitrogen atmosphere placement part 51.

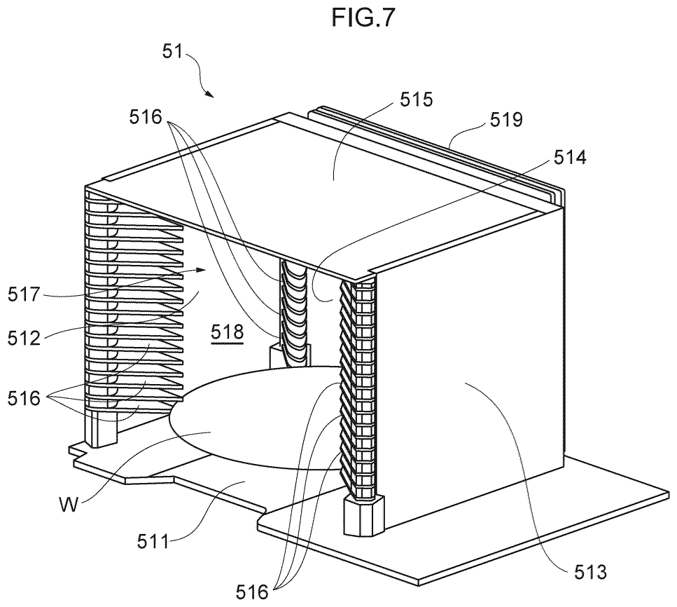

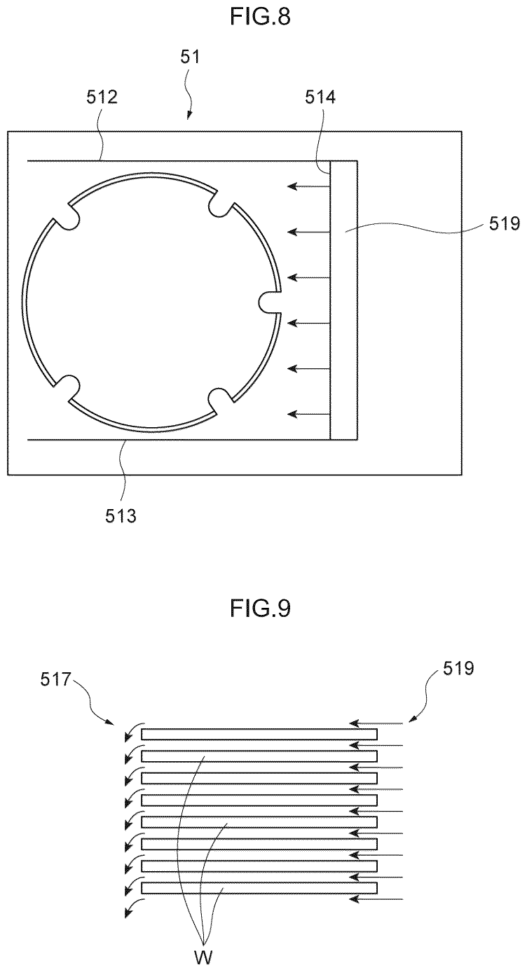

Next, details of the nitrogen atmosphere placement part 51 arranged in the transfer device 105 will be explained with reference to FIG. 7 to FIG. 12. FIG. 7 is a perspective view schematically illustrating the nitrogen atmosphere placement part 51 of a slot structure that is arranged in the transfer device 105 of the fifth block G5. FIG. 8 is a plan view schematically illustrating the nitrogen atmosphere placement part 51 of the slot structure. Note that in FIG. 8, illustration of a part of a configuration (slot sectionizing part 516 to be mentioned later and the like) of the nitrogen atmosphere placement part 51 is omitted.

As illustrated in FIG. 7, the nitrogen atmosphere placement part 51 includes a base part 511, wall parts 512, 513, and 514, a roof part 515, and the plurality of slot sectionizing parts 516. The base part 511 is a bottom portion from which the wall parts 512, 513, and 514 erect. The wall parts 512 and 513 are parts that extend in the vertical direction so as to face each other. The wall part 514 is arranged so as to intersect with the wall parts 512 and 513, and further to extend in the vertical direction. An opening 517 is formed in a region facing the wall part 514, via which the wafer W is led in. The roof part 515 is arranged so as to face the base part 511, and further to cover upper surfaces of the wall parts 512, 513, and 514. A space sectioned by the base part 511, the wall parts 512, 513, and 514, and the roof part 515 is a housing space 518 that accommodates therein the wafers W. As described above, the opening 517 is formed in a part via which the wafers W are led in the housing space 518. The wall parts 512, 513, and 514 are arranged in three of four surrounding sides of the wafer W accommodated in a slot except for the opening 517 that is a leading-in port of the wafer W.

The plurality of slot sectionizing parts 516 is a part that determines a plurality of slots for accommodating the respective wafers W. The plurality of slot sectionizing parts 516 is arranged in a boundary portion between the wall part 512 and the opening 517, a boundary portion between the wall part 512 and the wall part 514, a boundary portion between the wall part 513 and the wall part 514, and a boundary portion between the wall part 513 and the opening 517. Each of the plurality of slot sectionizing parts 516 extends towards the center of the wafer W. In a case where the four slot sectionizing parts 516 having the same height among the slot sectionizing parts 516 extending towards the center of the wafer W from the above-mentioned four boundary portions are assumed to be a single set, the single wafer W is placed on the slot sectionizing parts 516 of above-mentioned set. As described above, the wafers W can be placed at respective heights in the vertical direction. The nitrogen atmosphere placement part 51 is a placing part having a so-called slot structure that accommodates therein the wafers W in respective slots. In FIG. 7, the single wafer W alone is illustrated, which is placed on the slot sectionizing parts 516 at a lowermost stage.

Moreover, as illustrated in FIG. 8, the nitrogen atmosphere placement part 51 includes a nitrogen supplying unit 519 (namely, second nitrogen supplying unit) that supplies nitrogen to the housing space 518. The nitrogen supplying unit 519 is formed in the wall part 514 that is a region facing the opening 517, and supplies nitrogen towards the opening 517 so as to supply nitrogen to the housing space 518. For example, the nitrogen supplying unit 519 includes holes formed in the wall part 514, and may have a configuration that quides nitrogen delivered from a nitrogen supply source (not illustrated) towards an opening 517a. According to the above-mentioned configuration, it is possible to deliver nitrogen towards a space surrounded by the three wall parts 512, 513, and 514 except for the opening 517 while efficiently housing the plurality of wafers W by the slot structure, so that it is further possible to cause the wafer W to wait in environment having a high nitrogen concentration.

FIG. 9 is a diagram illustrating a side flow in the nitrogen atmosphere placement part 51 of the slot structure. In FIG. 9, flows of nitrogen (namely, flows indicated by arrows) between the wafers W in the housing space 518 are schematically illustrated. As illustrated in FIG. 9, nitrogen supplied from the nitrogen supplying unit 519 flows between the wafers W so as to reach the opening 517, and further is discharged downward at the opening 517.

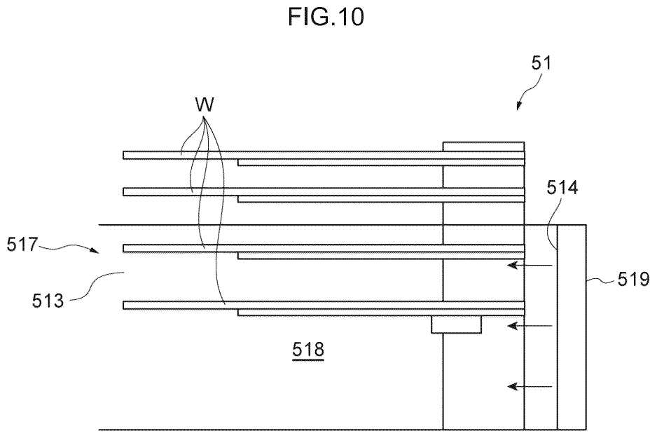

The nitrogen atmosphere placement part 51 having a slot structure is not limited to the above-mentioned mode. FIG. 10 is a side view schematically illustrating the nitrogen atmosphere placement part 51 of a slot structure according to a modification. In the nitrogen atmosphere placement part 51 illustrated in FIG. 10, a part (for example, two on upper side) of the wafers W are arranged above the housing space 518 that is surrounded by the wall parts 512, 513, and 514. According to the above-mentioned configuration, for example, in a mode such that a transfer device accesses from other than the opening 517a, a region corresponding to the upper two wafers W can be accessed by the transfer device from a plurality of directions without being interrupted by the wall parts 512, 513, and 514. The nitrogen atmosphere placement part 51 having the slot structure according to the modification may be provided in the transfer device 103 of the third block G3, for example.

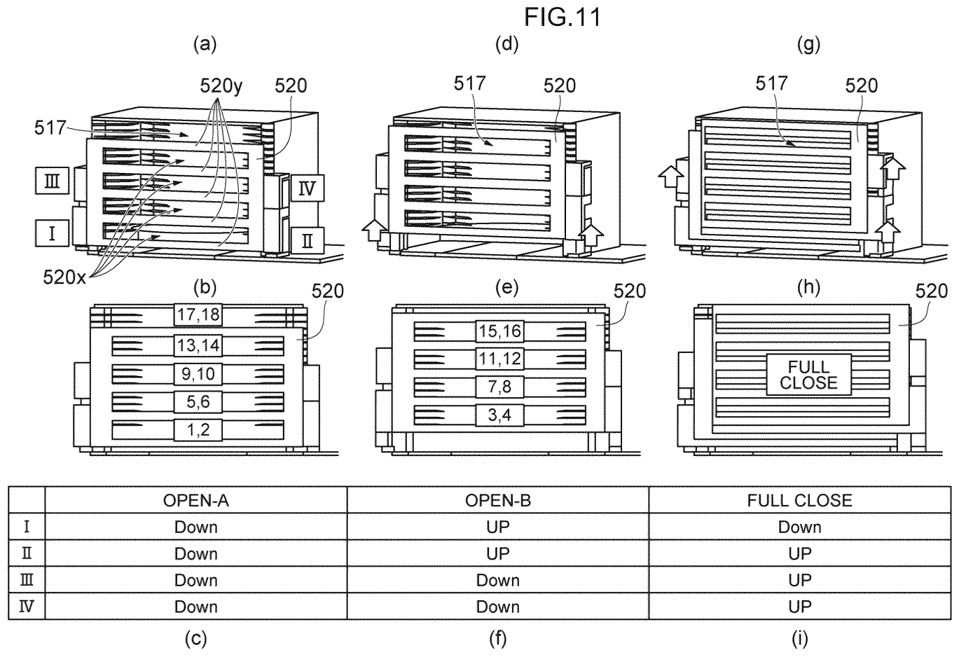

The opening 517 of the nitrogen atmosphere placement part 51 having a slot structure may be further provided with four shutters 520 (see FIG. 11 (a) and the like) as an opening/closing unit. As illustrated in FIG. 11 (a) and the like, each of four passing regions 520x is formed in the four shutters 520, which allows access of a transfer device. Shield parts 520y are provided in upper and lower portion of each of the four passing regions 520x, which do not allow access of a transfer device. In other words, the shield part 520y is provided between the passing regions 520x and 520x that are adjacent in the vertical direction. The four shutters are arranged in respective positions that are separated along a direction (namely, depth direction) from the opening 517 towards an inner part of the nitrogen atmosphere placement part 51. The shutters 520 relatively move in the vertical direction so as to open a region facing a part of the plurality of slots in the opening 517. As a configuration for opening/closing the four shutters 520, cylinders I, II, III, and IV are provided. The cylinder I is a cylinder that vertically moves corresponding two of the four shutters 520. The cylinder II is a cylinder that vertically moves two, which are not moved by the cylinder I, of the four shutters 520. The cylinder III is a cylinder that vertically moves one alone, which are moved by the cylinder I, of the two shutters 520 that are moved by the cylinder I. The cylinder III is fixed with respect to the cylinder I such that whole of the cylinder III vertically operates in accordance with a vertical operation of the cylinder I by the same distance. The cylinder IV is a cylinder that vertically moves one alone, which are moved by the cylinder II, of the two shutters 520 that are moved by the cylinder II. The cylinder IV is fixed with respect to the cylinder II such that whole of the cylinder IV vertically operates in accordance with a vertical operation of the cylinder II by the same distance. A vertical movement width of each of the shutters 520 by a single vertical movement of each of the cylinders I, II, III, and IV is the same. In other words, a relative position between two shutters corresponding to the cylinder I is adjusted by a vertical operation of the cylinder III, and a relative position between other two shutters corresponding to the cylinder II is adjusted by a vertical operation of the cylinder IV.

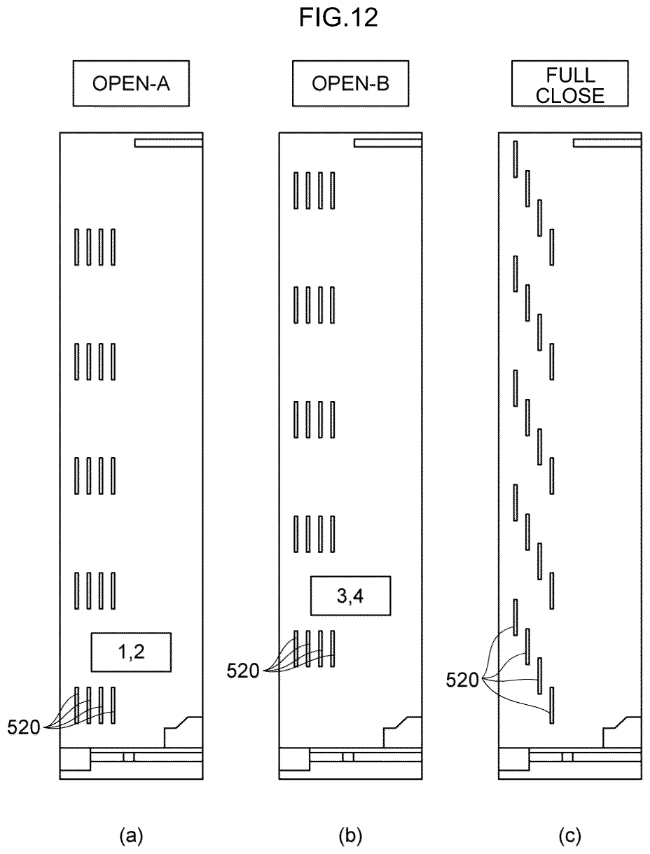

In the above-mentioned shutters 520, for example, a region for allowing access of a transfer device may be changed by three modes. Herein, a “OPEN-A” mode, a “OPEN-B” mode, and a “FULL-CLOSE” mode are exemplified as the three modes. FIG. 11 (a) is a perspective view illustrating a shutter state under the “OPEN-A” mode, FIG. 11 (b) is a front view illustrating a shutter state under the “OPEN-A” mode, and FIG. 11 (c) is a table indicating UP or DOWN of cylinders under the “OPEN-A” mode. FIG. 11 (d) is a perspective view a shutter state under the “OPEN-B” mode, FIG. 11 (e) is a front view illustrating a shutter state under the “OPEN-B” mode, and FIG. 11 (f) is a table indicating UP or DOWN of the cylinders under the “OPEN-B” mode. FIG. 11 (g) is a perspective view a shutter state under the “FULL-CLOSE” mode, FIG. 11 (h) is a front view illustrating a shutter state under the “FULL-CLOSE” mode, and FIG. 11 (i) is a table indicating UP or DOWN of the cylinders under the “FULL-CLOSE” mode. FIG. 12 (a) is a side view schematically illustrating a shutter state under the “OPEN-A” mode, and FIG. 12 (b) is a side view schematically illustrating a shutter state under the “OPEN-B” mode. FIG. 12 (c) is a side view schematically illustrating a shutter state under the “FULL-CLOSE” mode.

As illustrated in FIG. 11 (c), under the “OPEN-A” mode, all of the cylinders I, II, III, and IV are in a Down state. In this case, as illustrated in FIG. 12 (a), all of the four shutters 520 are located at the same height, the passing regions 520x are overlapped with one another, and the shield parts 520y are overlapped with one another. As illustrated in FIG. 11 (b), for example, assume that the housing space 518 is capable of housing therein the 18 wafers W at most. In this case, the first, second, fifth, sixth, ninth, 10th, 13th, 14th, 17th, and 18th wafers W from the bottom can be housed via the passing regions 520x. Additionally, the third, fourth, seventh, eighth, 11th, 12th, 15th, and 16th wafers W from the bottom cannot be housed by the shield parts 520y.

As illustrated in FIG. 11 (f), under the “OPEN-B” mode, the cylinders I and II are in an UP state, and the cylinders III and IV are in a Down state. In this case, as illustrated in FIG. 12 (b), all of the four shutters 520 are located at the same height, the passing regions 520x are overlapped with one another, and the shield parts 520y are overlapped with one another. On the other hand, the cylinders I and II are in an UP state, thus, the four shutters 520 has moved upward by one step compared with the state illustrated in FIG. 12 (a). In this case, as illustrated in FIG. 11 (e), for example, the third, fourth, seventh, eighth, 11th, 12th, 15th, and 16th wafers W from the bottom can be housed via the passing regions 520x.

Additionally, the first, second, fifth, sixth, ninth, 10th, 13th, 14th, 17th, and 18th wafers W from the bottom cannot be housed by the shield parts 520y.

As illustrated in FIG. 11 (i), under the “FULL-CLOSE” mode, the cylinder I alone is in a Down state, the cylinders II, III, and IV are in an UP state. In this case, as illustrated in FIG. 12 (c), all of the four shutters 520 are located at respective heights that are different from one another. Thus, as illustrated in FIG. 12 (c), each of the passing regions 520x of the four shutters 520 are overlapped with the shield part 520y of the other shutters 520. In this case, as illustrated in FIG. 11 (h), any of the wafers W cannot access (namely, be housed in) the housing space 518 by the shield part 520y.

Each of the “OPEN-A” mode and the “OPEN-B” mode may be also referred to as an opening mode of the nitrogen atmosphere placement part 51, in which a region for allowing access of a transfer device is different. The “FULL-CLOSE” mode may be also referred to as a single closing mode of the nitrogen atmosphere placement part 51. In other words, the nitrogen atmosphere placement part 51 having a slot structure illustrated in FIG. 8 (a) and the like is set to one of a plurality of opening modes in which an overlapped height of passing regions of a plurality of shutters is different, in accordance with a housing position to be accessed by a transfer device. A closing mode is set in a state where overlapped heights of passing regions of a plurality of shutters are deviated from one another.

According to the configuration, it is possible to easily control a region for allowing access of a transfer device by using a binary control of UP/Down on any of the cylinders I, II, III, and IV corresponding to each of the shutters 520. A distance of a vertical operation by each cylinder in changing between open/close is decided by a pitch of passing regions that are vertically arranged. Thus, a plurality of passing regions is vertically arranged by a plurality of shield parts for each shutter, and thus a distance of a vertical operation by a single cylinder is restrained, in other words, a vertical operation mechanism of shutters including cylinders becomes compact. In the present embodiment, for each of the shutters, a vertical width of a single shield part is set to be smaller than a vertical width of a single passing region. Note that the number of the shutters 520 may be two instead of four; however, it is preferable that the number of the shutters 520 be four from viewpoints for effectively shuttering the opening 517 and securing rigidity of the shutters. In a case where a region for allowing access of a transfer device is decided by the shutters 520, it is possible to effectively prevent a case where disturbance effects due to movement of a transfer device or the like affect the wafer W housed in the housing space 518.

As described above, the plurality of shutters is located at positions that are deviated along a depth direction; however, all of the shutters may be apart from one another in all of the opening mode and the closing mode. For example, as illustrated in FIG. 9, a gap in the depth direction may be arranged between two shutters. Even in a case of a closing mode, it is sufficient that a concentration of supplied gas is maintained to be a desired amount when gas (for example, nitrogen) is continuously Supplied to the inner part, so that the inner space is not necessarily completely sealed. For example, gas is supplied at a flow volume that is enough to maintain a concentration of the supplied gas to be a desired amount while maintaining all of the shutters not to be in contact with each other so as to form small gaps therebetween. The above-mentioned desired amount is a value that is appropriately set in accordance with various process conditions (for example, film thickness, target CD, and the like) as conditions in which a concentration of the gas is higher than that of air so as not to generate a pattern defect in MOR.

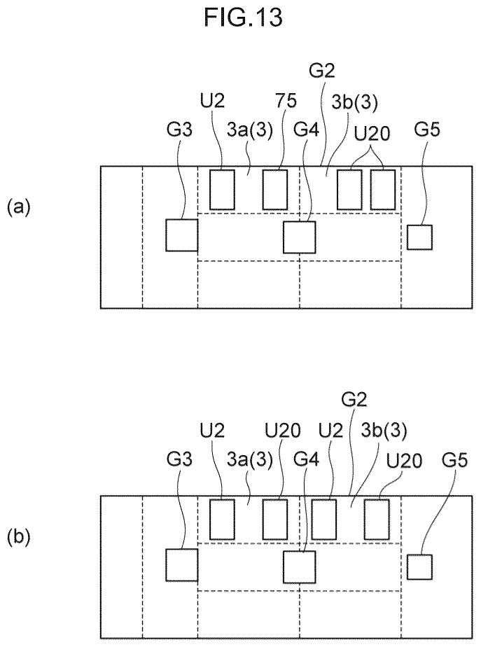

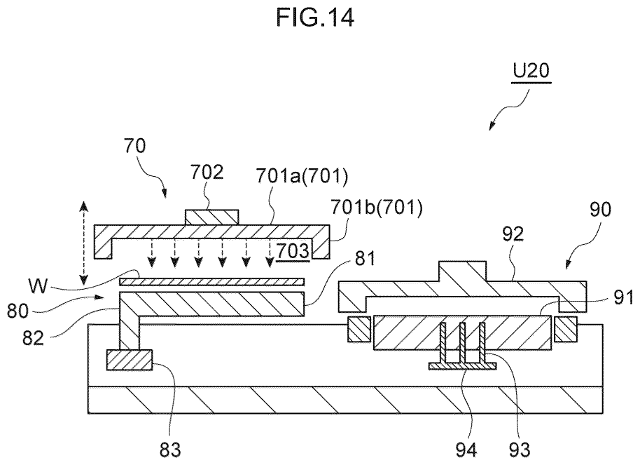

A third configuration example for handling resists having a plurality of types will be explained with reference to FIG. 13 and FIG. 14. FIG. 13 (a) is a plan view schematically illustrating one example of a layout of heat processing units U2 and U20 and the like in the second block G2. In the example illustrated in FIG. 13 (a), the heat processing unit U2 (namely, second heat processing unit) and the heat processing unit U20 (namely, first heat processing unit) are provided as a thermal treatment module that is arranged in at least one layer of the second block G2 (namely, processing block). Specifically, the single heat processing unit U2 and a cooling unit 75 are arranged in the second block G2 close to the first region 3a. Additionally, the two heat processing units U20 are arranged in the second block G2 close to the second region 3b. Each of the heat processing units U2 and U20 includes a heat plate and a cooling plate that is arranged together with the heat plate, and are arranged in the same layer of the second block G2 as described above.

As illustrated in FIG. 14, the heat processing unit U20 further includes a nitrogen atmosphere adjustment unit 70 that is arranged above a cooling plate 81 so as to configure a second processing device that executes a process on the MOR film formed wafer W. A basic configuration of the heat processing unit U2 is the same or similar to a configuration of the heat processing unit U20; however, the heat processing unit U2 does not include the nitrogen atmosphere adjustment unit 70 so as to constitute a first processing device that executes a process on the CAR film formed wafer W.

The nitrogen atmosphere adjustment unit 70 provided in the heat processing unit U20 will be explained. As illustrated in FIG. 14, the nitrogen atmosphere adjustment unit 70 is a nitrogen atmosphere placement part having a chamber structure. FIG. 14 is a cross-sectional view schematically illustrating the nitrogen atmosphere adjustment unit 70 having a chamber structure, which is arranged on the cooling plate 81 connected with a heat plate 91 of the heat processing unit U20. The heat processing unit U20 is configured to execute, on the wafer W, a thermal treatment including a heating treatment and a cooling process. As illustrated in FIG. 14, the heat processing unit U20 includes the nitrogen atmosphere adjustment unit 70, a cooling unit 80, and a heating unit 90. Note that a configuration including the cooling unit 80 and the heating unit 90 may be enclosed by a housing (not illustrated).

The heating unit 90 executes a heating treatment for heating the wafer W on the wafer W. For example, the heating unit 90 includes the heat plate 91, a lid body 92, a plurality of lift pins 93, and a drive unit 94. The heat plate 91 is a plate for heating the placed wafer W. The heat plate 91 is formed in disk-shaped, for example. A heater (not illustrated) is provided to a surface of the heat plate 91, which is on an opposite side of a surface on which the wafer W is placed. Electric current flows through the heater, and the heater generates heat so as to raise the temperature of the heat plate 91. Thus, the wafer W placed on the heat plate 91 is heated. The lid body 92 is formed to surround a placement surface of the heat plate 91. The lift pins 93 are pins for lifting/lowering the wafer W. The lift pins 93 extend along the vertical direction so as to penetrate through the heat plate 91. The plurality of lift pins 93 (for example, three pins) is arranged along a peripheral direction around the center of the heat plate 91. The drive unit 94 lifts/lowers the lift pins 93 on the basis of an operation instruction of the control device 100. For example, the drive unit 94 include a driving source such as an electric motor.

The cooling unit 80 executes, on the processed wafer W, a cooling process for reducing the temperature of the wafer W down to a target temperature. The cooling unit 80 transfers the wafer W to and from the wafer transfer device 33 outside of the heat processing unit U2. For example, the cooling unit 80 includes the cooling plate 81, a connecting bracket 82, and a drive unit 83. The cooling plate 81 is a plate (namely, cooling plate) for cooling the wafer W. In a state where the wafer W having been heated by the heating unit 90 is located above the cooling plate 81, the cooling plate 81 cools the wafer W down to a target temperature. The cooling plate 81 may be formed in disk-shaped. The cooling plate 81 may be made of aluminum, silver, copper, or the like. A coolant flow path (not illustrated) is formed in the cooling plate 81, through which coolant flows, such as water for cooling and gas for cooling. Coolant flowing in the cooling plate 81 takes heat from the wafer W so as to reduce the temperature of the wafer W. The connecting bracket 82 is connected with the cooling plate 81. The connecting bracket 82 is configured to be movable in one horizontal direction. For example, the connecting bracket 82 is movable along a guide rail (not illustrated) extending across the heating unit 90. The drive unit 83 operates on the basis of an operation instruction of the control device 100 so as to move the connecting bracket 82 back-and-forth along a horizontal direction. For example, the drive unit 83 includes a driving source such as an electric motor.

The nitrogen atmosphere adjustment unit 70 is arranged on the cooling plate 81. The nitrogen atmosphere adjustment unit 70 raises a nitrogen concentration of atmosphere in surroundings of the wafer W placed on the cooling plate 81 than that of air. The nitrogen atmosphere adjustment unit 70 includes a lid body 701 and a nitrogen supplying unit 702.

The lid body 701 is formed so as to surround the cooling plate 81 that is a support surface for supporting the wafer W. The lid body 701 includes a top board 701a and a side wall portion 701b. The top board 701a is formed in disk-shaped having a diameter that is the same or similar to that of the cooling plate 81. The top board 701a is arranged so as to face the cooling plate 81 in the vertical direction. The side wall portion 701b is formed so as to extend downward from an outer periphery of the top board 701a.

The nitrogen supplying unit 702 is arranged near the center of the top board 701a to be configured to supply nitrogen to a space 703 that is surrounded by the cooling plate 81 and the lid body 701 (specifically, top board 701a and side wall portion 701b). For example, the nitrogen supplying unit 702 is connected to a nitrogen supply source (not illustrated) via a supply pipe (not illustrated). The nitrogen supplying unit 702 delivers nitrogen into the space 703 to be capable of causing the cooling unit 80 to cool the wafer W under environment having a high nitrogen concentration.

For example, the cooling unit 75 illustrated in FIG. 13 (a) has a configuration of the above-mentioned heat processing unit U20 without the heating unit 90, in other words, has a configuration including the cooling unit 80 and the nitrogen atmosphere adjustment unit 70. The above-mentioned cooling unit 75 configures a second processing device that executes a process on the MOR film formed wafer W.

Note that a layout of the heat processing units U2 and U20 and the like is not limited to the mode illustrated in FIG. 13 (a), and may be a mode illustrated in FIG. 13 (b), for example. In other words, as illustrated in FIG. 13 (b), the single heat processing unit U2 and the single heat processing unit U20 are arranged in the second block G2 close to the first region 3a. The single heat processing unit U2 and the single heat processing unit U20 may be arranged in the second block G2 close to the second region 3b.

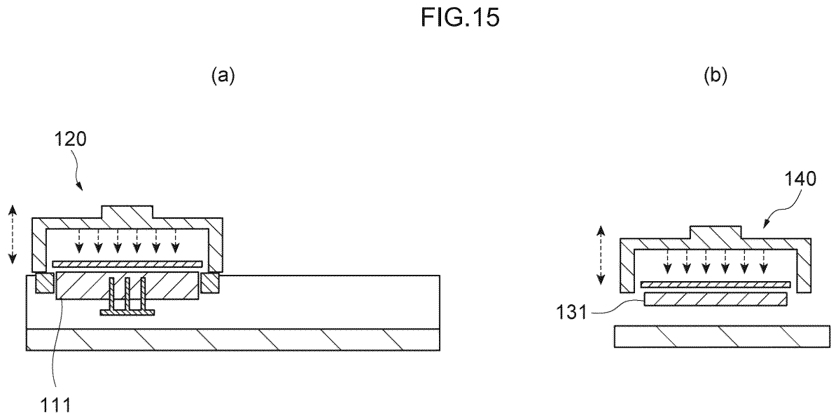

A fourth configuration example for handling resists having a plurality of types will be explained with reference to FIG. 15 (a). FIG. 15 (a) is a cross-sectional view schematically illustrating one example of the nitrogen atmosphere adjustment unit having a chamber structure that is arranged on an independently-provided cooling plate 111. In an example illustrated in FIG. 15 (a), a nitrogen atmosphere adjustment unit 120 (namely, second nitrogen atmosphere placement part) having a chamber structure is provided corresponding to the cooling plate 111 arranged in the transfer device 104 of the fourth block G4 (see FIG. 2). For example, the wafer W is placed on the cooling plate 111, and further the cooling plate 111 cools the wafer W in a process after the above-mentioned process executed in the cooling plate 81 that is connected to the heat plate 91. Compared with the above-mentioned cooling plate 81, the cooling plate 111 may be a cooling plate according to high precision cooling in consideration of a temperature distribution of regions in the wafer W. A configuration of the nitrogen atmosphere adjustment unit 120 is the same or similar to that of the nitrogen atmosphere adjustment unit 70.

In the above-mentioned third configuration example and the above-mentioned fourth configuration example, the lid body 701 may be configured to be vertically lifted and lowered with respect to the cooling plate 81 by a not-illustrated lid body lifting and lowering mechanism. For example, in a case where the lid body 701 is located in a predetermined lifted position, the wafer W is transferred between a cooling plate (see 81, 111, or 131 in drawings) and a transfer device (for example, wafer transfer device 33) that transfers the wafer W. In a case where the lid body 701 is in a predetermined lowered position, the wafer W is cooled above a cooling plate. In this case, nitrogen may be supplied from a nitrogen supplying unit in a state where a space on or above a cooling plate mounting thereon the wafer W is not sealed, by forming a gap under a side wall of the lid body 701 located in a predetermined lowered position, without enclosing a side of the wafer W by using the lid body 701. In this case, the lifting and lowering lid body 701 can be thinned, a transfer device accesses the above of a cooling plate, and thus a stroke for raising the lid body 701 can be shortened, so that it is possible to reduce a necessary space of a nitrogen atmosphere adjustment unit. In other words, because a necessary space of the nitrogen atmosphere adjustment unit is small, many nitrogen atmosphere adjustment units can be arranged in a wafer processing system, so that it is possible to optimize a patterning process.

In the transfer device 104, a plurality of housing spaces accommodating therein the wafers W is formed in a vertically multistage manner. The nitrogen atmosphere adjustment unit 120, in which the wafer W is placed in environment whose nitrogen concentration in atmosphere is set to be higher than that of air, is arranged in a housing space in at least one of the transfer devices 104. The nitrogen atmosphere adjustment unit 120 constitutes a second processing device that executes a process on the MOR film formed wafer W. Although not illustrated, a second air atmosphere placement part is provided corresponding to the cooling plate 111 that is arranged in the transfer device 104 of the fourth block G4 (see FIG. 2). The second air atmosphere placement part is provided in at least one of housing spaces of the fourth block G4 without the nitrogen atmosphere adjustment unit 120. The wafer W is placed on the second air atmosphere placement part in atmospheric environment. The second air atmosphere placement part constitutes a first processing device that executes a process on the CAR film formed wafer W.

A fifth configuration example for handling resists having a plurality of types will be explained with reference to FIG. 15 (b). FIG. 15 (b) is a cross-sectional view schematically illustrating another example of the nitrogen atmosphere adjustment unit having the chamber structure that is arranged on an independently-provided cooling plate 131. In an example illustrated in FIG. 15 (b), a nitrogen atmosphere adjustment unit 140 having a chamber structure is provided corresponding to the cooling plate 131 arranged in the transfer device 103 of the third block G3 (see FIG. 2). In this case, the nitrogen atmosphere adjustment unit 140 is arranged between the second block G2 (namely, processing block), which executes a thermal treatment and the like, and the cassette station 2 that is a carry-in/out part of the wafer W. For example, in a process after the above-mentioned process in the cooling plate 81 connected with the heat plate 91, the wafer W is placed on the cooling plate 131 so as to cool the wafer W. Compared with the above-mentioned cooling plate 81, the cooling plate 131 may be a cooling plate according to high precision cooling in consideration of a temperature distribution of regions in the wafer W. A configuration of the nitrogen atmosphere adjustment unit 140 is the same or similar to that of the nitrogen atmosphere adjustment unit 70.

In the transfer device 103, a plurality of housing spaces accommodating therein the wafers W is formed in a vertically multistage manner. The nitrogen atmosphere adjustment unit 140, in which the wafer W is placed in environment whose nitrogen concentration in atmosphere is set to be higher than that of air, is arranged in a housing space in at least one of the transfer devices 103. The nitrogen atmosphere adjustment unit 140 constitutes a second processing device that executes a process on the MOR film formed wafer W. Although not illustrated, an air atmosphere placement part is provided corresponding to the cooling plate 131 that is arranged in the transfer device 103 of the third block G3 (see FIG. 2). The air atmosphere placement part is provided in at least one of housing spaces of the third blocks G3 without the nitrogen atmosphere adjustment unit 140. The wafer W is placed on the atmosphere placement part in atmospheric environment. The air atmosphere placement part constitutes a first processing device that executes a process on the CAR film formed wafer W.

### Edge Cleaning in MOR Processing

In the layer 31 provided with the MOR dedicated applying device 162 and the layer 31 provided with the MOR dedicated developing device 164 in the first block G1 illustrated in FIG. 5, after an applying process or a developing process, an edge cleaning process may be executed on the MOR applied wafer W. In this case, the wafer processing system 1 further includes a cleaning module configured to clean the MOR film applied wafer W.

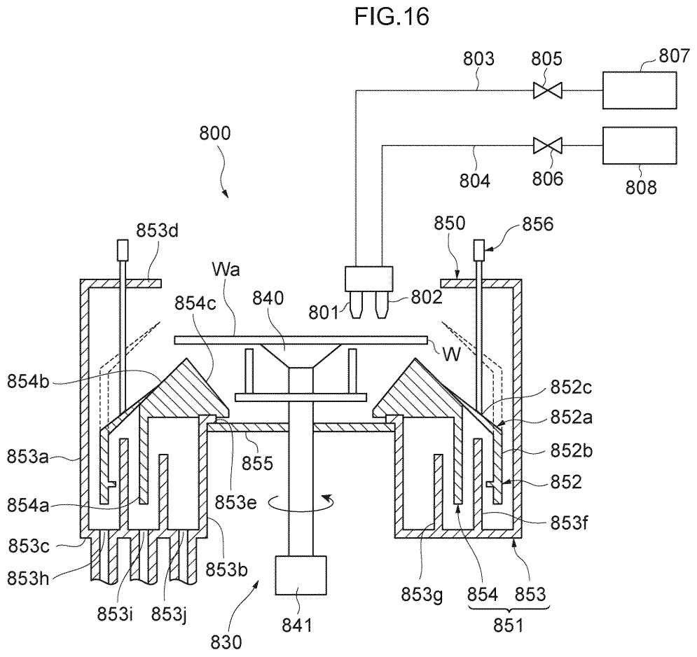

FIG. 16 is a cross-sectional view schematically illustrating the outline of a cleaning module 800. The cleaning module 800 is a cleaning module that is provided instead of the single MOR dedicated developing device 164 that is an MOR dedicated developing module. The cleaning module 800 is provided instead of the MOR dedicated developing device 164 (namely, MOR dedicated developing device 164 close to transfer device 103) on the most downstream side of a developing process among the four MOR dedicated developing devices 164 illustrated in FIG. 5, for example.

As illustrated in FIG. 16, the cleaning module 800 includes a rotation holding unit 830. The rotation holding unit 830 holds and rotates the wafer W. For example, the rotation holding unit 830 includes a holding unit 840 and a rotation drive unit 841. The holding unit 840 is a spin chuck that is configured to support the horizontally-arranged wafer W in a state where a front surface thereof faces the above, and further to absorb (for example, vacuum suction) and hold the wafer W. For example, the rotation drive unit 841 causes an electric motor as a power source to rotate the holding unit 840 around a vertical rotational center. Thus, the wafer W is caused to rotate. A cup 850 is provided around the wafer W held by the holding unit 840. Details of the cup 850 will be mentioned later.

The cleaning module 800 includes a first cleaning nozzle 801 (namely, first cleaning-liquid supplying unit), which supplies first cleaning liquid of hydrophilic cleaning liquid to the wafer W, and a second cleaning nozzle 802 (namely, second cleaning-liquid supplying unit) that supplies second cleaning liquid of hydrophobic cleaning liquid to the wafer W. Note that the first cleaning liquid may be non-polar solvent (for example, PGMEA) instead of the hydrophilic cleaning liquid. Note that the second cleaning liquid may be polar solvent (for example, TMAH aqueous solution) instead of the hydrophobic cleaning liquid. The cleaning module 800 constitutes a second processing device that executes a process on the wafer W to which an MOR film is applied. A cleaning module 900 may supply first cleaning liquid from a first cleaning nozzle 981, and then may supply second cleaning liquid from a second cleaning nozzle 982. The cleaning module 900 may supply second cleaning liquid from the second cleaning nozzle 982, and then may supply first cleaning liquid from the first cleaning nozzle 981.

The first cleaning liquid is organic solvent composed of molecules having an ester structure or an ether structure, or mixture of the organic solvent and an acidic material, for example. The organic solvent may include, for example, Methyl Acetate, Butyl Acetate, Ethyl Acetate, Isopropyl Acetate, Amyl Acetate, Isoamyl Acetate, Ethyl Methoxyacetate, or Ethyl Ethoxyacetate. The organic solvent may include 2-Heptanone, Propylene Glycol Monomethyl Ether Acetate (PGMEA), Isopropyl Alcohol, or Ethylene Glycol Monoethyl Ether Acetate. The organic solvent may include Ethylene Glycol Monopropyl Ether Acetate, Ethylene Glycol Monobutyl Ether Acetate, Ethylene Glycol Monophenyl Ether Acetate, or Diethylene Glycol Monomethyl Ether Acetate. The organic solvent may include Diethylene Glycol Monopropyl Ether Acetate, Diethylene Glycol Monoethyl Ether Acetate, Diethylene Glycol Monophenyl Ether Acetate, or Diethylene Glycol Monobutyl Ether Acetate. The organic solvent may include Diethylene Glycol Monoethyl Ether Acetate, 2-Methoxybutyl Acetate, 3-Methoxybutyl Acetate, 4-Methoxybutyl Acetate, or 3-Methyl-3-Methoxybutyl Acetate. The organic solvent may include 3-Ethyl-3-Methoxybutyl Acetate, Propylene Glycol Monoethyl Ether Acetate, Propylene Glycol Monopropyl Ether Acetate, or 2-Ethoxybutyl Acetate. The organic solvent may include 4-Ethoxybutyl Acetate, 4-Propoxybutyl Acetate, 2-Methoxypentyl Acetate, 3-Methoxypentyl Acetate, or 4-Methoxypentyl Acetate. The organic solvent may include 2-Methyl-3-Methoxypentyl Acetate, 3-Methyl-3-Methoxypentyl Acetate, 3-Methyl-4-Methoxypentyl Acetate, or 4-Methyl-4-Methoxypentyl Acetate. The organic solvent may include Propylene Glycol Diacetate, Methyl Formate, Ethyl Formate, Butyl Formate, Propyl Formate, Ethyl Lactate, Butyl Lactate, Propyl Lactate, Ethyl Carbonate, Propyl Carbonate, Butyl Carbonate, Methyl Pyruvate, or Ethyl Pyruvate. The organic solvent may include Propyl Pyruvate, Butyl Pyruvate, Methyl Acetoacetate, Ethyl Acetoacetate, Methyl Propionate, Ethyl Propionate, Propyl Propionate, Isopropyl Propionate, or Methyl-2-Hydroxypropionate. The organic solvent may include Ethyl-2-Hydroxypropionate, Methyl-3-methoxypropionate, Ethyl-3-methoxypropionate, Ethyl-3-ethoxypropionate, Propyl-3-Methoxypropionate, or a combination of the above two or more. The above-mentioned acidic material includes an organic acid, inorganic acid, or a combination thereof; and the organic acid is organic carboxylic acid such as acetic acid and citric acid.

The second cleaning liquid includes solution of an alkaline material, for example. The above-mentioned alkaline material may include inorganic alkalis such as Sodium Hydroxide, Potassium Hydroxide, Sodium Carbonate, Sodium Silicate, Sodium Metasilicate, and ammonia water; primary amines such as Ethylamine and n-Propylamine; or Diethylamine, for example. The above-mentioned alkaline material may include secondary amines such as Di-n-butylamine; tertiary amines such as Triethylamine and Methyl-diethylamine; and alcohol amines such as Dimethylethanolamine and Triethanolamine. The above-mentioned alkaline material may include Tetramethylammonium Hydroxide, Tetraethylammonium Hydroxide, Tetrabutylammonium Hydroxide, Tetrapropylammonium Hydroxide, or Methyltriethylammonium Hydroxide. The above-mentioned alkaline material may include Trimethylethylammonium Hydroxide, Dimethyldiethylammonium Hydroxide, or Trimethyl(2-Hydroxyethyl)ammonium Hydroxide (i.e., choline). The above-mentioned alkaline material may include Triethyl(2-hydroxyethyl)ammonium Hydroxide, Dimethyldi(2-hydroxyethyl)ammonium Hydroxide, or Diethyldi(2-hydroxyethyl)ammonium Hydroxide. The above-mentioned alkaline material may include quaternary ammonium Salts such as Methyl-tri(2-hydroxyethyl)ammonium Hydroxide, Ethyl-Tri(2-hydroxyethyl)ammonium Hydroxide, or Tetra(2-hydroxyethyl)ammonium Hydroxide. The above-mentioned alkaline material may include cyclic amines such as pyrrole or piperidine. The above-mentioned alkaline material may include water, for example. In this case, an appropriate amount of alcohols such as iso-Propyl Alcohol, and/or surfactants such as nonionic surfactant may be added. The above-mentioned alkaline material may include alcohols (e.g., Methanol, Ethanol, 1-Propanol, 2-Propanol, 1-Butanol, Ethane-1, 2-Diol, Propane-1, 2,3-Triol, etc.) as solvent. The water-repellent cleaning liquid may be water. Specifically, the development material having a polarity may be neutral water or deionized water. The water-repellent cleaning liquid may include mixture of water and an acidic material. The above-mentioned acidic material may include organic sulfonic acids, organic carboxylic acids (acetic acid, citric acid, etc.), inorganic acids, or combinations thereof. As the water-repellent cleaning liquid, quaternary ammonium salt solution may be preferably employed, and solution of Tetraethylammonium Hydroxide or Tetrabutylammonium Hydroxide may be more preferably employed. A concentration of solution of Tetraethylammonium Hydroxide or Tetrabutylammonium Hydroxide is preferably 0.1% to 70% (mass ratio), and is more preferably 2% to 10% (mass ratio).

After liquid processing (namely, applying process or developing process), a hydrophobic portion and a hydrophilic portion are generated in the wafer W in some cases. The hydrophobic portion is an unexposed part of the wafer W. The hydrophilic portion is an intermediate exposure region generated in a boundary between the exposed part and the unexposed part. In a case where the above-mentioned hydrophobic portion and the above-mentioned hydrophilic portion remain in an edge portion of the wafer W, the remaining portions are considered to be carried in another device via a transfer device as an extraneous substance, and further to adhere to another wafer to be a defect cause as cross contamination. Thus, it is important to clean a hydrophobic portion and a hydrophilic portion remaining on an edge portion of the wafer W. The first cleaning liquid is solvent that dissolves a hydrophobic portion of the wafer W. The second cleaning liquid is solvent that dissolves a hydrophilic portion of the wafer W.

As illustrated in FIG. 16, the cleaning module 800 includes the first cleaning nozzle 801 (namely, first cleaning-liquid supplying unit) that supplies first cleaning liquid to a surface Wa of the wafer W, a flow path 803, an open/close valve 805, and a solvent supplying mechanism 807. The cleaning module 800 further includes the second cleaning nozzle 802 (namely, second cleaning-liquid supplying unit) that supplies second cleaning liquid to the surface Wa of the wafer W, a flow path 804, an open/close valve 806, and a solvent supplying mechanism 808. The first cleaning nozzle 801 is connected to the solvent supplying mechanism 807 via the flow path 803 including the open/close valve 805. As described above, the flow path 803 is a supply route of the first cleaning liquid so as to cause the first cleaning liquid to flow between the first cleaning nozzle 801 and the solvent supplying mechanism 807 that is a supply source of the first cleaning liquid. The second cleaning nozzle 802 is connected to the solvent supplying mechanism 808 via the flow path 804 including the open/close valve 806. As described above, the flow path 804 is a supply route of the second cleaning liquid so as to cause the second cleaning liquid to flow between the second cleaning nozzle 802 and the solvent supplying mechanism 808 that is a supply source of the second cleaning liquid.

The cup 850 includes a cup body 851 and a movable cup 852 that is movable with respect to the cup body 851. The cup body 851 includes a cup body 853 and a fixed cup 854 that is fixed with respect to the cup body 853.

The cup body 853 includes a circular outer peripheral wall 853a and a circular inner peripheral wall 853b, and the outer peripheral wall 853a and the inner peripheral wall 853b are formed to extend in the vertical direction. An inner diameter of the outer peripheral wall 853a is formed to be greater than a diameter of the wafer W, an outer diameter of the inner peripheral wall 853b is formed to be smaller than the diameter of the wafer W, and a height of the inner peripheral wall 853b is formed to be smaller than a height of the outer peripheral wall 853a.

The cup body 853 further includes a bottom wall 853c that connects a lower end of the outer peripheral wall 853a and a lower end of the inner peripheral wall 853b, and a top wall 853d that extends in an inner periphery direction thereof from an upper end of the outer peripheral wall 853a; and an upper side of the inner peripheral wall 853b is opened. A protrusion 853e is formed in an upper end of the inner peripheral wall 853b, which extends in the inner periphery direction, and the protrusion 853e is sandwiched between the fixed cup 854 and a holding plate 855 so as to fix the cup body 853.

The fixed cup 854 constitutes a circular inner-structure body located between the outer peripheral wall 853a and the inner peripheral wall 853b. The fixed cup 854 includes a circular peripheral wall 854a that is located between the outer peripheral wall 853a and the inner peripheral wall 853b. An outer peripheral surface of an upper end of the fixed cup 854 is formed by an outer inclined surface 854b that gradually lowers as the position is closer to an outer peripheral side. A step is formed in the outer inclined surface 854b. Note that a lower end of the outer inclined surface 854b is continuously formed with an outer peripheral surface of the peripheral wall 854a. Moreover, the fixed cup 854 includes an inner inclined surface 854c in an inner portion of the outer inclined surface 854b, which gradually lowers towards an inner side.

The movable cup 852 is a circular member configured to be vertically movable between the outer peripheral wall 853a of the cup body 853 and the fixed cup 854, includes a distribution unit 852a in an upper end thereof, and further includes a peripheral wall 852b on a lower side of the distribution unit 852a. The distribution unit 852a is for separately discharging first cleaning liquid and second cleaning liquid, and an upper surface of the distribution unit 852a is formed by an inclined surface 852c that gradually lowers as the position is closer to the outer peripheral side. The peripheral wall 852b is formed in circular-shaped, an inner diameter of the peripheral wall 852b is greater than an outer diameter of the peripheral wall 854a of the fixed cup 854, and an outer diameter of the peripheral wall 852b is smaller than an inner diameter of the outer peripheral wall 853a of the cup body 853. An outer peripheral end of the inclined surface 852c of the distribution unit 852a is continuously formed with an outer peripheral surface of the peripheral wall 852b. A lifting/lowering unit 856 for lifting/lowering the movable cup 852 is arranged above the movable cup 852.

On the bottom wall 853c of the cup body 853, two circular-shaped partition walls 853f and 853g are formed between the outer peripheral wall 853a and the inner peripheral wall 853b. On the bottom wall 853c, a recovery port 853h for recovering first cleaning liquid is formed between the outer peripheral wall 853a and an outer peripheral side of the partition wall 853f. Additionally, on the bottom wall 853c, a recovery port 853i for recovering second cleaning liquid is formed between the partition walls 853f and 853g, and a recovery port 853j for recovering mist of cleaning liquid is formed between an inner peripheral side of the partition wall 853g and the inner peripheral wall 853b. A not-illustrated pump, etc. may be connected with the recovery port 853h, the recovery port 853i, and the recovery port 853j.

In a case of a cleaning process with the use of first cleaning liquid, as illustrated in FIG. 16, in the MOR dedicated developing device 164, the movable cup 852 is lowered, and further a pump connected with the recovery port 853h is driven. Thus, it is possible to lead first cleaning liquid, which substantially horizontally splashed due to rotation of the wafer W, to the recovery port 853h between the distribution unit 852a of the movable cup 852 and the outer peripheral wall 853a of the cup body 853, so as to recover the first cleaning liquid via the recovery port 853h.

In a case of a cleaning process with the use of second cleaning liquid, as illustrated in FIG. 16, in the MOR dedicated developing device 164, the movable cup 852 is raised, and further a pump connected with the recovery port 853i is driven. Thus, it is possible to lead second cleaning liquid having splashed due to rotation of the wafer W and fallen-off second cleaning liquid having gone around to a lower side of the wafer W, to the recovery port 853i from between the distribution unit 852a of the movable cup 852 and the fixed cup 854, so as to recover the second cleaning liquid via the recovery port 853i.

Note that the cleaning module 800 may be replaced with the single MOR dedicated applying device 162 that is an MOR dedicated applying module. In this case, the above-mentioned cleaning module 800 may be replaced with the MOR dedicated applying device 162 (namely, MOR dedicated applying device 162 close to transfer device 104) on the most downstream side in an applying process of the four MOR dedicated applying devices 162 illustrated in FIG. 5, for example.

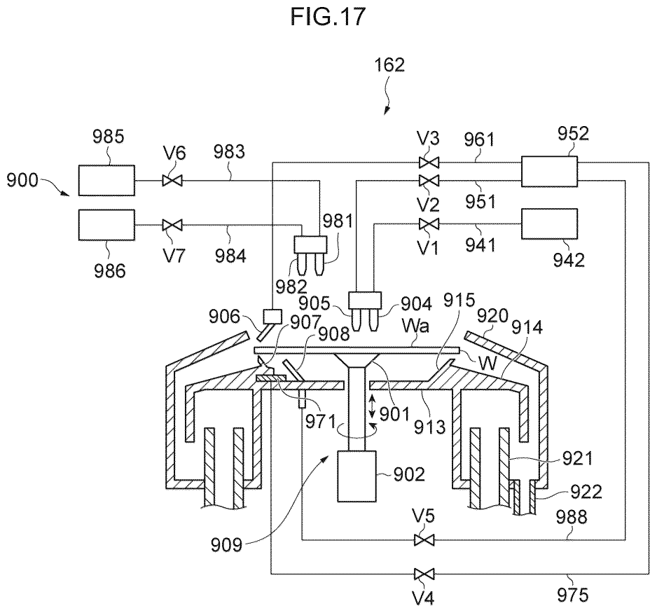

FIG. 17 is a cross-sectional view schematically illustrating the cleaning module 900. The cleaning module 900 is arranged in the MOR dedicated applying device 162 that is an MOR dedicated applying module. All of the MOR dedicated applying devices 162 may be provided with the respective cleaning modules 900, or the single cleaning module 900 alone may be arranged in the single MOR dedicated applying device 162 (namely, MOR dedicated applying device 162 close to transfer device 104) alone on the most downstream side, for example.

As illustrated in FIG. 17, the MOR dedicated applying device 162 supplies processing liquid for forming an MOR film to the surface Wa of the wafer W, so as to form the above-mentioned pre-bake resist film. The MOR dedicated applying device 162 forms a pre-bake resist film on the surface Wa of the wafer W, and then supplies removal solution to a periphery portion of the wafer W, so as to remove a periphery portion of the pre-bake resist film.

The MOR dedicated applying device 162 includes a rotation holding unit 909. The rotation holding unit 909 holds and rotates the wafer W. For example, the rotation holding unit 909 includes a holding unit 901 and a rotation drive unit 902. The holding unit 901 is a spin chuck that is configured to support the wafer W, which is horizontally arranged in a state where a front surface of the wafer W faces the above, and further to absorb (for example, by vacuum suction) and hold the supported wafer W. For example, the rotation drive unit 902 causes an electric motor as a power source to rotate the holding unit 901 around a vertical rotational center by using an electric motor or the like, so as to rotate the wafer W.

A cup 920 is provided around the wafer W held by the holding unit 901, gas in a lower portion of the cup 920 is discharged via an exhaust pipe 921, and the lower portion of the cup 920 is connected with a drain tube 922. A circular plate 913 is provided below the holding unit 901 so as to surround a shaft, and a ring-shaped and mountain-shaped part 914, whose cross-sectional shape is formed in mountain-shaped, is formed around the circular plate 913. In an apex portion of the mountain-shaped part 914, a protruding piece 915 is provided for preventing mist flowing in the cup 920 from flowing into a back surface side of the wafer W.

The MOR dedicated applying device 162 includes an application liquid nozzle 904 configured to discharge application liquid, and a solvent nozzle 905 configured to discharge solvent that is solvent of application liquid. The application liquid nozzle 904 is connected to an application liquid supplying mechanism 942 via a flow path 941 including an open/close valve V1. The solvent nozzle 905 is a nozzle that is used in a pre-process to be executed before discharging application liquid to the wafer W, and is connected to a solvent supplying mechanism 952 via a flow path 951 including an open/close valve V2. Each of the application liquid nozzle 904 and the solvent nozzle 905 is configured to be movable between the above of the center of the wafer W and a retreat position outside the cup 920 by a not-illustrated movement mechanism.

Moreover, the MOR dedicated applying device 162 includes a removal liquid nozzle 906 that is a nozzle for removing a film in a periphery portion of the wafer W, a bevel cleaning nozzle 907 for removing a film in a bevel portion, and a back surface cleaning nozzle 908. The removal liquid nozzle 906 is an Edge Bead Removal (EBR) nozzle that discharges removal solution (namely, processing liquid) to a periphery portion of the wafer W. The removal liquid nozzle 906 is configured to discharge removal solution to a surface of the wafer W which is inner than a bevel portion of the wafer W held by the holding unit 901 such that the removal solution goes towards a downstream side in a rotational direction of the wafer W. For example, the removal liquid nozzle 906 is formed in linearly-tubular-shaped, and a leading end thereof opens as a discharge port of the removal solution. For example, the removal liquid nozzle 906 is configured to be movable by a not-illustrated movement mechanism, between a processing position for discharging removal solution to a periphery portion of the wafer W and a retreat position outside the cup 920.

The bevel cleaning nozzle 907 discharges removal solution from a back surface side of the wafer W held by the holding unit 901 towards a bevel portion thereof. The bevel cleaning nozzle 907 is configured to freely move along a base 971, and the base 971 is arranged in a not-illustrated cutout portion that is formed in the mountain-shaped part 914, for example.

The back surface cleaning nozzle 908 discharges cleaning liquid to a back surface that is inner than a bevel portion of the wafer W held by the holding unit 901. The back surface cleaning nozzle 908 is configured such that a landing point of the cleaning liquid on the wafer W is inner than an outer periphery of the wafer W by, for example, 70 mm when discharging cleaning liquid towards the wafer W, for example. The two bevel cleaning nozzles 907 and the two back surface cleaning nozzles 908 are provided to the MOR dedicated applying device 162, for example.

Both of the removal solution and the cleaning liquid according to the present embodiment are solvents of an application film, and the removal liquid nozzle 906 is connected to the solvent supplying mechanism 952 via a flow path 961 including an open/close valve V3. As described above, the flow path 961 is a supply route of removal solution, which is processing liquid, and further causes the removal solution to flow between the removal liquid nozzle 906 and the solvent supplying mechanism 952 that is a supply source of the removal solution. The bevel cleaning nozzle 907 is connected to the solvent supplying mechanism 952 via a flow path 975 including an open/close valve V4. The back surface cleaning nozzle 908 is connected to the solvent supplying mechanism 952 via a flow path 988 including an open/close valve V5.

The cleaning module 900 includes the first cleaning nozzle 981 (namely, first cleaning-liquid supplying unit) that supplies first cleaning liquid to the wafer W, which is hydrophilic cleaning liquid, and the second cleaning nozzle 982 (namely, second cleaning-liquid supplying unit) that supplies second cleaning liquid to the wafer W, which is hydrophobic cleaning liquid. The cleaning module 900 constitutes a second processing device that executes a process on the wafer W to which an MOR film is applied. Details of the first cleaning liquid and the second cleaning liquid are as described above. The cleaning module 900 may supply first cleaning liquid from the first cleaning nozzle 981, and then may supply second cleaning liquid from the second cleaning nozzle 982. The cleaning module 900 may clean the wafer W also for exerting functions of EBR, in other words, for removing an unnecessary MOR film in a periphery portion. The cleaning liquid is supplied by the cleaning module 900 after supply of an application film and further before bake. In a case where cleaning liquid is supplied before bake, it is possible to avoid a case where a residue to be cleaned aggregates and further is cured by the bake.

The cleaning module 900 includes the first cleaning nozzle 981 (namely, first cleaning-liquid supplying unit), a flow path 983, an open/close valve V6, a solvent supplying mechanism 985, the second cleaning nozzle 982 (namely, second cleaning-liquid supplying unit), a flow path 984, an open/close valve V7, and a solvent supplying mechanism 986. The first cleaning nozzle 981 is connected to the solvent supplying mechanism 985 via the flow path 983 including the open/close valve V6. As described above, the flow path 983 is a supply route of first cleaning liquid, and causes the first cleaning liquid to flow between the first cleaning nozzle 981 and the solvent supplying mechanism 985 that is a supply source of the first cleaning liquid. The second cleaning nozzle 982 is connected to the solvent supplying mechanism 986 via the flow path 984 including the open/close valve V7, As described above, the flow path 984 is a supply route of second cleaning liquid, and causes the second cleaning liquid to flow between the second cleaning nozzle 982 and the solvent supplying mechanism 986 that is a supply source of the second cleaning liquid.

Note that the cleaning module 900 may be arranged in the MOR dedicated developing device 164 that is an MOR dedicated developing module. All of the MOR dedicated developing devices 164 may be provided with the respective cleaning modules 900, or the single cleaning module 900 alone may be arranged in the MOR dedicated developing device 164 (namely, MOR dedicated developing device 164 close to transfer device 103) alone on the most downstream side, for example.

### Actions and Effects

Actions and effects of the wafer processing system 1 according to the present embodiment will be explained.

The wafer processing system 1 is a substrate processing apparatus that executes a process according to EUV patterning so as to include a plurality of first processing devices each of which executes a process on the wafer W to which CAR is applied, and a plurality of second processing devices each of which executes a process on the wafer W on which MOR is applied. A processing space of the first processing devices and a processing space of the second processing devices are sectioned from each other. Each of the second processing devices executes a process corresponding to a process executed by the corresponding first processing device.

The wafer processing system 1 according to the present embodiment is provided with both of the first processing devices each of which executes a process on the wafer W to which CAR is applied, and the second processing devices each of which executes a process on a substrate to which MOR is applied. Thus, processes corresponding to both of CAR and MOR, which are resists for EUV, can be realized by a single substrate processing apparatus. A processing space of the first processing device and a processing space of the second processing device are sectioned from each other, for example, so that it is possible to avoid a case where a process for the wafer W to which MOR is applied affects the wafer W to which CAR is applied. Thus, processes corresponding to both of CAR and MOR can be appropriately executed. Moreover, each of the second processing devices executes a process corresponding to a process executed by the corresponding first processing device, so that it is possible to execute similar processes (namely, processes corresponding to each other) on both of the wafer W to which CAR is applied and the wafer W to which MOR is applied. As described above, in accordance with the wafer processing system 1 according to the present embodiment, it is possible to appropriately realize processes corresponding to both of CAR and MOR by a single substrate processing apparatus, and further to efficiently execute EUV patterning.

The wafer processing system 1 further includes the first block G1 that is a processing block obtained by vertically laminating a plurality of layers. At least one of the first processing devices and at least one of the second processing devices may be arranged in respective different layers in the first block G1. As described above, the first processing devices and the second processing devices are arranged in different layers in the first block G1. Thus, for example, it is possible to avoid a case where a process for the wafer W to which MOR is applied affects the wafer W to which CAR is applied, and further to appropriately execute processes corresponding to both of CAR and MOR.

The wafer processing system 1 further includes a thermal treatment module arranged in at least one layer in the second block G2. The thermal treatment module includes the heat processing units U20 and U2 arranged in the same layer, each of which includes the heat plate 91 and the cooling plate 81 adjacently arranged to the heat plate 91. The heat processing unit U20 further includes the nitrogen atmosphere adjustment unit 70 that is arranged above the cooling plate 81 to set a nitrogen concentration of atmosphere around the wafer W to be higher than that of air, so as to configure the second processing device. The heat processing unit U2 does not include the nitrogen atmosphere adjustment unit 70 so as to configure the first processing device.

For example, in a case where the wafer w, to which MOR is applied in normal atmospheric environment (namely, air), is placed on the cooling plate 81, CD fluctuates due to a waiting time interval or the like, and there presents possibility that a preferable pattern is not obtained. In this point, in the heat processing unit U20 constituting the second processing device, the nitrogen atmosphere adjustment unit 70 is arranged above the cooling plate 81, so that it is possible to reduce fluctuation in CD of the wafer W to which MOR is applied. Furthermore, in the heat processing unit U2 constituting the first processing device, the nitrogen atmosphere adjustment unit 70 is not provided, so that it is possible to appropriately execute a process on the wafer W, to which CAR is applied, in atmospheric environment.

The wafer processing system 1 further includes the interface station 4 including the transfer device 105 that carries the wafer W to and from an exposure device, and in which a plurality of housing spaces accommodating therein the wafers W is formed in a vertically multistage manner. The wafer processing system 1 further includes the nitrogen atmosphere placement part 51 on which the wafer W is placed in environment whose nitrogen concentration of atmosphere is set to be higher than that of air, and is arranged in at least one housing space of the transfer devices 105. The wafer processing system 1 further includes the air atmosphere placement part 55 on which the wafer W is placed in atmospheric environment, and that is arranged in at least one of housing spaces without the nitrogen atmosphere placement part 51 among a plurality of housing spaces of the transfer device 105. The nitrogen atmosphere placement part 51 constitutes at least one of the second processing devices. The air atmosphere placement part 55 constitutes at least one of the first processing devices.

According to the above-mentioned configuration, the wafer W, on which MOR is applied, is placed on the nitrogen atmosphere placement part 51 constituting the second processing device, so that it is possible to appropriately reduce fluctuation in CD of the wafer W. The wafer W, on which CAR is applied, is placed on the air atmosphere placement part 55 constituting the first processing device, and thus it is possible to keep the wafer W, on which CAR is applied and that is to wait in atmospheric environment, waiting in a preferable environment. In other words, it is possible to appropriately realize processes corresponding to both of CAR and MOR. Regarding amount of a fluctuation effect in CD of the wafer W caused by atmospheric environment, that of MOR is considered to be greater than that of CAR, Thus, the wafer W, on which MOR is applied, is caused to wait in nitrogen atmosphere, and in a case of CAR, the above-mentioned waiting is not executed, so that it is possible to proceed the process for CAR without waiting formation of nitrogen atmosphere in addition to reduction of nitrogen consumption.

The processing station 3 is divided into the first region 3a and the second region 3b in the left-and-right direction intersecting with the vertical direction. The wafer processing system 1 further includes the transfer device 104 that is arranged between the first region 3a and the second region 3b and in which a plurality of housing spaces accommodating therein the wafers W is formed in a vertically multistage manner. The wafer processing system 1 further includes the nitrogen atmosphere adjustment unit 120 in which a substrate is placed in environment whose nitrogen concentration of atmosphere is set to be higher than that of air, and that is arranged in at least one of housing spaces in the transfer device 104. The wafer processing system 1 further includes a second air atmosphere placement part in which the wafer W is placed in atmospheric environment, and that is arranged in at least one housing space without the nitrogen atmosphere adjustment unit 120 of the plurality of housing spaces in the transfer device 104.

According to the above-mentioned configuration, also in the transfer device 104, it is possible to cause the wafer W, to which MOR is applied, to wait in environment having a high nitrogen concentration, and further to cause the wafer W, to which CAR is applied, to wait in atmospheric environment. In other words, it is possible to appropriately realize processes corresponding to both of CAR and MOR.

The wafer processing system 1 further includes the cleaning module 800 or the cleaning module 900, which cleans the wafer W to which MOR is applied. The cleaning module 800 includes the first cleaning nozzle 801 that supplies first cleaning liquid to the wafer W, which is hydrophilic cleaning liquid, and the second cleaning nozzle 802 that supplies second cleaning liquid to the wafer W, which is hydrophobic cleaning liquid. The cleaning module 800 constitutes at least one second processing device.

The wafer W, to which MOR is applied, includes a hydrophobic part of an unexposed part in a state where reaction does not proceed and ligands are left, and a hydrophilic part that has received some exposure energy to replace come-off ligands therein with hydroxy groups. Particularly, in a periphery portion including an edge, it is preferable that both thereof be cleaned. In this case, from the cleaning module 800 or the cleaning module 900 constituting the second processing device, hydrophilic cleaning liquid and hydrophobic cleaning liquid are supplied, so that it is possible to appropriately clean the above-mentioned hydrophobic part and hydrophilic part.

The first cleaning liquid, which is hydrophilic cleaning liquid, may be solvent that dissolves a hydrophobic portion that is an unexposed part of the wafer W. The second cleaning liquid, which is hydrophobic cleaning liquid, may be solvent that dissolves a hydrophilic portion that is an intermediate exposure region arranged in a boundary between an unexposed part and an exposed part of the wafer W. According to the above-mentioned configuration, a hydrophobic portion and a hydrophilic portion are dissolved to be removed, so that it is possible to appropriately clean the wafer W.

The cleaning module 800 may supply hydrophilic cleaning liquid from the first cleaning nozzle 801, and then may supply hydrophobic cleaning liquid from the second cleaning nozzle 802. According to the above-mentioned configuration, a remaining film is reduced by the hydrophilic cleaning liquid, so that it is possible to efficiently execute the cleaning.

So far, the present disclosure disclosed in the present application has been explained, the present disclosure is not limited to the above-mentioned embodiment. For example, “at least one nitrogen atmosphere placement part on which a substrate is placed in environment having a nitrogen concentration of atmosphere that is set to be higher than that of air” has been explained to supply nitrogen; however, gas other than nitrogen may be supplied. Specifically, as gas that affects formation of a pattern of the wafer W; air in which ammonia, oxygen, or carbon dioxide is adjusted, acidic gas such as gas including, for example, acetic acid, low-humidity air, or the like may be supplied.

The above-mentioned substrate processing apparatus may further include a reaction accelerating unit in which a substrate is placed in environment having a concentration of reaction accelerating gas for accelerating reaction of a film of a metal containing resist (MOR) which is set to be higher than that of air. The reaction accelerating unit constitutes at least one of the plurality of second processing devices which executes a process on a substrate to which MOR is applied. The reaction accelerating gas is gas that accelerates reaction of an MOR film, such as high-humidity gas, CO₂, and highly concentrated CO₂ air. As described above, a substrate is caused to wait in environment for accelerating reaction of an MOR film, so that it is possible to reduce fluctuation in property of an MOR film between substrates.

The reaction accelerating unit may be arranged in the transfer device 105 of the fifth block G5, the transfer device 104 of the fourth block G4, or the transfer device 103 of the third block G3, for example. The reaction of accelerating unit may be arranged in the heat processing unit U20 of the second block G2, for example.

In a case where the reaction accelerating unit is arranged in the transfer device 105 of the fifth block G5, the nitrogen atmosphere placement part 51 may function as the reaction accelerating unit. In this case, the nitrogen supplying unit 519 (see FIG. 7) of the nitrogen atmosphere placement part 51 may supply reaction accelerating gas instead of nitrogen (or in addition to nitrogen).

In a case where the reaction accelerating unit is arranged in the transfer device 104 of the fourth block G4, the nitrogen supplying unit of the nitrogen atmosphere adjustment unit 120 (see FIG. 15 (a)) may supply reaction accelerating gas instead of nitrogen (or in addition to nitrogen).

In a case where the reaction accelerating unit is arranged in the transfer device 103 of the third block G3, the nitrogen supplying unit of the nitrogen atmosphere adjustment unit 140 (see FIG. 15 (b)) may supply reaction accelerating gas instead of nitrogen (or in addition to nitrogen).

In a case where the reaction accelerating unit is arranged in the heat processing unit U20 of the second block G2, the nitrogen supplying unit 702 (see FIG. 14) of the nitrogen atmosphere adjustment unit 70 may supply reaction accelerating gas instead of nitrogen (or in addition to nitrogen).

The reaction accelerating unit may be a reaction accelerating gas supplying unit that is arranged separately from a configuration for supplying nitrogen.

It is sufficient that the reaction accelerating unit sets a concentration of reaction accelerating gas accelerating reaction of a film of a metal containing resist (MOR) in a predetermined area to be higher than that of air, and further may employ a configuration other than the above-mentioned one for supplying reaction accelerating gas. For example, the reaction accelerating unit may have a configuration for executing pressure-reduced exhaust so as to set the above-mentioned concentration of reaction accelerating gas to be higher than that of air.

Finally, as a specific application example of the reaction accelerating unit, reaction acceleration after exposure in a low humidity environment will be explained. The reaction accelerating unit may have a configuration for supplying low humidity gas (namely, gas having humidity that is lower than outside air) as reaction accelerating gas to an exposed substrate. In a case where a reaction of MOR is mediated by water, a dehydration condensation reaction proceeds after hydrolysis. On the basis thereof, a space, to which low humidity gas is supplied, easily includes water. Thus, in an exposed region in which reaction has more proceeded than an unexposed part, a dehydration condensation reaction, which is a phenomenon in the second half of the reaction of MOR, is considered to accelerate by a low humidity environment while maintaining a selection ratio (exposure contrast) with respect to the unexposed part. For such reasons, low humidity gas is considered to be reaction accelerating gas with respect to an exposed substrate on which an MOR film is formed.

Finally, various exemplary embodiments included in the present disclosure will be described in the following E1 to E11.

### “E1”

A substrate processing apparatus that executes a process related to EUV patterning includes: a plurality of first processing devices each of which executes a process for applying a chemically amplified resist to a substrate; and a plurality of second processing devices each of which executes a process for applying a metal containing resist to a substrate. Processing spaces of the first processing devices and processing spaces of the second processing devices are sectioned from each other, and the plurality of second processing devices executes processes corresponding to the respective first processing devices.

### “E2”

The substrate processing apparatus according to “E1” further includes: a processing block in which a plurality of layers is vertically laminated, wherein at least one of the first processing devices and at least one of the second processing device are separately arranged in different layers of the layers in the processing block.

### “E3”

The substrate processing apparatus according to “E1” or “E2” further includes: a thermal treatment module that is arranged in at least one of the layers in the processing block. The thermal treatment module includes a first heat processing unit and a second heat processing unit each of which includes a heat plate and a cooling plate arranged with the heat plate, the first heat processing unit and the second heat processing unit being arranged in a same layer of the layers. The first heat processing unit is configured to further include a nitrogen atmosphere adjustment unit that is arranged above the cooling plate to set a nitrogen concentration of atmosphere around a substrate that is placed on the cooling plate to be higher than a nitrogen concentration of air. The first heat processing unit is configured to constitute at least one of the second processing devices. The second heat processing unit does not include the nitrogen atmosphere adjustment unit to constitute at least one of the first processing devices.

### “E4”

The substrate processing apparatus according to any one of “E1” to “E3” further includes: an interface station that is connected with the processing block to carry a substrate to/from an exposure device, and includes a first tower in which a plurality of housing spaces for accommodating therein substrates is formed in a vertically multistage manner. The substrate processing apparatus further includes: a first nitrogen atmosphere placement part on which a substrate is placed in environment whose nitrogen concentration of atmosphere is set to be higher than a nitrogen concentration of air, the first nitrogen atmosphere placement part being arranged in at least one of the housing spaces of the first tower. The substrate processing apparatus further includes: a first air atmosphere placement part on which a substrate is placed in atmospheric environment, and is arranged in at least one of the housing spaces without the first nitrogen atmosphere placement part of the housing spaces in the first tower. The first nitrogen atmosphere placement part constitutes at least one of the second processing devices. The first air atmosphere placement part constitutes at least one of the first processing devices.

### “E5”

The substrate processing apparatus according to any one of “E1” to “E4”, wherein the processing block is divided into a first region and a second region in a left-and-right direction intersecting with a vertical direction. The substrate processing apparatus further includes: a second tower that carries a substrate between the first region and the second region, and in which a plurality of housing spaces accommodating therein substrates is formed in a vertically multistage manner. The substrate processing apparatus further includes: a second nitrogen atmosphere placement part on which a substrate is placed in environment whose nitrogen concentration of atmosphere is set to be higher than a nitrogen concentration of air, the second nitrogen atmosphere placement part being arranged in at least one of the housing spaces in the second tower. The substrate processing apparatus further includes: a second air atmosphere placement part on which a substrate is placed in atmospheric environment, the second air atmosphere placement part being arranged in at least one of the housing spaces of the second tower which is without the second nitrogen atmosphere placement part. The second nitrogen atmosphere placement part constitutes at least one of the second processing devices. The second air atmosphere placement part constitutes at least one of the first processing devices.

### “E6”

The substrate processing apparatus according to any one of “E1” to “E5” further includes: a cleaning module that cleans a substrate to which a metal containing resist is applied, wherein the cleaning module includes: a first cleaning-liquid supplying unit that supplies hydrophilic cleaning liquid to a substrate; and a second cleaning-liquid supplying unit that supplies hydrophobic cleaning liquid to a substrate. The cleaning module constitutes at least one of the second processing devices.

### “E7”

The substrate processing apparatus according to “E6”, wherein the hydrophilic cleaning liquid is solvent that dissolves a hydrophobic portion of a substrate, the hydrophobic portion being an unexposed part, and the hydrophobic cleaning liquid is solvent that dissolves a hydrophilic portion of a substrate, the hydrophilic portion being an intermediate exposure region arranged in a boundary between the unexposed part and the exposed part.

### “E8”

The substrate processing apparatus according to “E6” or “E7”, wherein the cleaning module supplies the hydrophilic cleaning liquid from the first cleaning-liquid supplying unit, and then supplies the hydrophobic cleaning liquid from the second cleaning-liquid supplying unit.

### “E9”

A substrate processing method that to be executed by a substrate processing apparatus that executes a process related to EUV patterning, the method includes: a first process for executing a process on a substrate on which a chemically amplified resist is to be applied; and a second process for executing a process on a substrate on which a metal containing resist is to be applied. A processing space in which the first process is executed and a processing space in which the second process is executed are sectioned from each other.

### “E10”

The substrate processing method according to “E9”, wherein the second process includes: a first cleaning liquid supplying process for supplying hydrophilic cleaning liquid to a substrate to which the metal containing resist is applied; and a second cleaning liquid supplying process for supplying hydrophobic cleaning liquid to a substrate to which the metal containing resist is applied.

### “E11”

The substrate processing apparatus according to any one of “E1” to “E8” further includes: a reaction accelerating unit in which a substrate is placed in environment whose concentration of reaction accelerating gas is set to be higher than a concentration of reaction accelerating gas of air, the reaction accelerating gas accelerating reaction of a film of the metal containing resist, wherein the reaction accelerating unit constitutes at least one of the second processing devices.

### REFERENCE SIGNS LIST

1: Wafer processing system, 3: Processing station, 3a: First region, 3b: Second region, 4, 4A:

Interface station, 51: Nitrogen atmosphere placement part, 55: Air atmosphere placement part, 70: Nitrogen atmosphere adjustment unit, 81: Cooling plate, 91: Heat plate, 104; Transfer device, 105: Transfer device, 120: Nitrogen atmosphere adjustment unit, 140: Nitrogen atmosphere adjustment unit, 800, 900: Cleaning module, 801, 981: First cleaning nozzle, 802, 982: Second cleaning nozzle

1. A substrate processing apparatus that executes a process related to EUV patterning comprising:
a plurality of first processing devices each of which executes a process for applying a chemically amplified resist to a substrate; and
a plurality of second processing devices each of which executes a process for applying a metal containing resist to a substrate, wherein
processing spaces of the first processing devices and processing spaces of the second processing devices are sectioned from each other, and
the plurality of second processing devices executes processes corresponding to the respective first processing devices.

2. The substrate processing apparatus according to claim 1 further comprising:
a processing block in which a plurality of layers is vertically laminated, wherein
at least one of the first processing devices and at least one of the second processing device are separately arranged in different layers of the layers in the processing block.

3. The substrate processing apparatus according to claim 2 further comprising:
a thermal treatment module that is arranged in at least one of the layers in the processing block, wherein
the thermal treatment module includes a first heat processing unit and a second heat processing unit each of which includes a heat plate and a cooling plate arranged with the heat plate, the first heat processing unit and the second heat processing unit being arranged in a same layer of the layers,
the first heat processing unit is configured to:
further include a nitrogen atmosphere adjustment unit that is arranged above the cooling plate to set a nitrogen concentration of atmosphere around a substrate that is placed on the cooling plate to be higher than a nitrogen concentration of air; and
constitute at least one of the second processing devices, and
the second heat processing unit does not include the nitrogen atmosphere adjustment unit to constitute at least one of the first processing devices.

4. The substrate processing apparatus according to claim 2 further comprising:
an interface station that is connected with the processing block to carry a substrate to/from an exposure device, and includes a first tower in which a plurality of housing spaces for accommodating therein substrates is formed in a vertically multistage manner,
a first nitrogen atmosphere placement part on which a substrate is placed in environment whose nitrogen concentration of atmosphere is set to be higher than a nitrogen concentration of air, the first nitrogen atmosphere placement part being arranged in at least one of the housing spaces of the first tower; and
a first air atmosphere placement part on which a substrate is placed in atmospheric environment, and is arranged in at least one of the housing spaces without the first nitrogen atmosphere placement part of the housing spaces in the first tower, wherein
the first nitrogen atmosphere placement part constitutes at least one of the second processing devices, and
the first air atmosphere placement part constitutes at least one of the first processing devices.

5. The substrate processing apparatus according to claim 2, wherein
the processing block is divided into a first region and a second region in a left-and-right direction intersecting with a vertical direction, and
the substrate processing apparatus further comprises:
a second tower that carries a substrate between the first region and the second region, and in which a plurality of housing spaces accommodating therein substrates is formed in a vertically multistage manner;
a second nitrogen atmosphere placement part on which a substrate is placed in environment whose nitrogen concentration of atmosphere is set to be higher than a nitrogen concentration of air, the second nitrogen atmosphere placement part being arranged in at least one of the housing spaces in the second tower; and
a second air atmosphere placement part on which a substrate is placed in atmospheric environment, the second air atmosphere placement part being arranged in at least one of the housing spaces of the second tower which is without the second nitrogen atmosphere placement part, wherein
the second nitrogen atmosphere placement part constitutes at least one of the second processing devices, and
the second air atmosphere placement part constitutes at least one of the first processing devices.

6. The substrate processing apparatus according to claim 1 further comprising:
a cleaning module that cleans a substrate to which a metal containing resist is applied, wherein
the cleaning module includes:
a first cleaning-liquid supplying unit that supplies hydrophilic cleaning liquid to a substrate; and
a second cleaning-liquid supplying unit that supplies hydrophobic cleaning liquid to a substrate, and
the cleaning module constitutes at least one of the second processing devices.

7. The substrate processing apparatus according to claim 6, wherein
the hydrophilic cleaning liquid is solvent that dissolves a hydrophobic portion of a substrate, the hydrophobic portion being an unexposed part, and
the hydrophobic cleaning liquid is solvent that dissolves a hydrophilic portion of a substrate, the hydrophilic portion being an intermediate exposure region arranged in a boundary between the unexposed part and the exposed part.

8. The substrate processing apparatus according to claim 7, wherein
the cleaning module supplies the hydrophilic cleaning liquid from the first cleaning-liquid supplying unit, and then supplies the hydrophobic cleaning liquid from the second cleaning-liquid supplying unit.

9. A substrate processing method to be executed by a substrate processing apparatus that executes a process related to EUV patterning, the method comprising:
a first process for executing a process on a substrate on which a chemically amplified resist is to be applied; and
a second process for executing a process on a substrate on which a metal containing resist is to be applied, wherein
a processing space in which the first process is executed and a processing space in which the second process is executed are sectioned from each other.

10. The substrate processing method according to claim 9, wherein
the second process includes:
a first cleaning liquid supplying process for supplying hydrophilic cleaning liquid to a substrate to which the metal containing resist is applied; and
a second cleaning liquid supplying process for supplying hydrophobic cleaning liquid to a substrate to which the metal containing resist is applied.

11. The substrate processing apparatus according to claim 1 further comprising:
a reaction accelerating unit in which a substrate is placed in environment whose concentration of reaction accelerating gas is set to be higher than a concentration of reaction accelerating gas of air, the reaction accelerating gas accelerating reaction of a film of the metal containing resist, wherein
the reaction accelerating unit constitutes at least one of the second processing devices.
